(19) United States
(12) Patent Application Publication
(10) Pub. No.: US 2025/0374532 A1
(43) Pub. Date: Dec. 4, 2025

(54) MEMORY DEVICE AND METHOD OF MANUFACTURING THE SAME

(71) Applicant: Seoul National University R&DB foundation, Seoul (KR)

(72) Inventor: Cheol Seong Hwang, Seoul (KR)

(21) Appl. No.: 19/227,718

(22) Filed: Jun. 4, 2025

(30) Foreign Application Priority Data
Jun. 4, 2024 (KR) 10-2024-0073277

(51) Int. Cl. H10B 12/00; H10D 1/68; H10D 64/27

(52) U.S. Cl. CPC H10B 12/488; H10B 12/03; H10B 12/05; H10B 12/482; H10D 1/714; H10D 64/519

(57) ABSTRACT

The present disclosure provides a method of manufacturing a memory device including forming a laminate including a first insulating layer and a first sacrificial layer sequentially laminated on the first insulating layer, a 1-1 gate insulating layer, a channel material layer, a 1-2 gate insulating layer, and a second sacrificial layer; patterning the laminate to form a patterned laminate having at least one pattern portion; forming a second recessed portion exposing the 1-1 and 1-2 gate insulating layers by recessing the first and second sacrificial layers in a capacitor formation area adjacent to the transistor formation area of the structure; defining a protruding channel portion from the channel material layer; and forming a capacitor in contact with the exposed upper, lower, and side surfaces of the protruding channel portion in the capacitor formation area.

### CROSS-REFERENCE TO RELATED APPLICATION

This application claims priority of Korean Patent Application No. 10-2024-0073277, filed on Jun. 4, 2024, in the KIPO (Korean Intellectual Property Office), the disclosure of which is incorporated herein entirely by reference.

### BACKGROUND OF THE INVENTION

### Field of the Invention

The present disclosure relates to a semiconductor/electronic device and a manufacturing method thereof, and more particularly to a memory device and a manufacturing method thereof.

### Description of the Related Art

There is an ongoing need to increase the performance of semiconductor devices and the density of semiconductor devices. Increasing the density of semiconductor devices by arranging the unit cells of semiconductor devices in two dimensions, i.e., planarly, is reaching its limits. Therefore, attempts are being made to increase the density of semiconductor devices by integrating the unit cells of semiconductor devices in three dimensions. In this regard, various attempts are being made to the of memory such as NAND devices and DRAM devices. In addition, research and development is ongoing to improve the performance and behavioral characteristics of memory devices.

In the fabrication of three-dimensional memory devices, for example, conventional methods use laminated structures in which Si/SiGe structures are repeatedly laminated hundreds of times, which suffer from very low productivity, high production costs, and high process difficulty. In particular, in forming the laminated structure, the epitaxial process time is long, and the epitaxial process difficulty is high. In addition, in the case of the conventional method, when the SiGe layer is removed, a problem may occur that the Si layer is structurally untenable.

In addition, in the manufacture of three-dimensional memory devices, only the end face of the channel is in contact with the electrodes of the capacitor, which increases the contact resistance. Furthermore, in the case of conventional structures, it is difficult to increase the effective area of the capacitor dielectric layer, so there are limitations and difficulties in securing high capacitance.

### SUMMARY OF THE INVENTION

The technical challenge of the present disclosure is to provide a memory device and a method for manufacturing the same that may achieve high integration and excellent performance while being easy to manufacture.

Furthermore, the technical challenge of the present disclosure is to provide a memory and a manufacturing method thereof that may low contact resistance and high characteristics by greatly enlarging the contact area between the channel layer and the capacitor and increasing the effective area of the capacitor dielectric layer.

The problems that the present disclosure is intended to solve are not limited to those mentioned above, and other problems not mentioned will be understood by those skilled in the art from the following description.

According to one embodiment of the present disclosure, forming a laminate comprising a first insulating layer and a first sacrificial layer, a first gate insulating layer, a channel material layer, a second gate insulating layer, and a second sacrificial layer laminated sequentially on the first insulating layer; patterning the laminate to form a patterned laminate having at least one patterned portion, the patterned portion having a shape extending in a first direction, and having etched regions on both sides of the patterned portion along a second direction perpendicular to the first direction; filling the etched regions on both sides of the at least one patterned portion with a separation material to define a structure comprising at least the patterned laminate; forming a first vertical hole through the patterned portion in a transistor forming region of the structure, and recessing the first and second sacrificial layers around the first vertical hole to form a first recess portion; forming word lines within the first recess to define a transistor comprising therein; forming bit lines associated with the channel material layer in a region corresponding to the first vertical hole in the structure; and recessing the first and second sacrificial layers in a capacitor forming region adjacent to the transistor forming region of the structure to form a second recess exposing the first 1-1 and first 1-2 gate insulating layers; The step of defining a protruding channel portion from the channel material layer by recessing the channel material layer and the first and second gate insulating layers in the second recess such that a protruding channel portion protruding into the second recess is retained and an upper surface and a side of the protruding channel portion is exposed; and a method of manufacturing a memory device comprising the steps of forming a capacitor in contact with the exposed upper surface and side of the protruding channel portion in the capacitor formation region.

The first insulating layer may comprise silicon oxide, and the first and second sacrificial layers may comprise silicon nitride.

The separating material may have a different material composition than the first insulating layer and the first and second sacrificial layers.

The patterned laminate may be formed to include a plurality of the patterned portions spaced apart from each other in the second direction and a patterned connection connecting the plurality of patterned portions in the second direction.

The word line may comprise a gate unit structure formed in response to the channel material layer of the transistor forming region, wherein a plurality of the gate unit structures may be spaced apart from each other in the second direction, and the word line may further comprise a connection line portion connecting the plurality of gate unit structures in the second direction, wherein the connection line portion may be formed at a position corresponding to the pattern connection portion.

The step of removing the separation material from the structure prior to the step of forming the bit lines; removing from the patterned laminate a portion of the channel material layer disposed at the patterned connections; and further filling the space around the plurality of patterned portions with a second separation material.

The step of defining the transistor by forming the word line, the transistor forming region comprising: forming a material layer for the word line filling at least a portion of the first vertical hole and the first recess; etching a region corresponding to the first vertical hole in the material layer for the word line to form a through hole; recessing a portion of the material layer for word lines exposed through the through-hole such that a first side of the channel material layer protrudes toward the through-hole than the material layer for word lines to form a recess region; and forming a fill insulating layer within the recess region.

The patterned laminate may be formed to include a plurality of the patterned portions spaced apart from each other in the second direction and patterned connections connecting the plurality of patterned portions in the second direction. In this case, the step of defining the transistor by forming the word line comprises: forming a material layer for the word line filling at least a portion of the first vertical hole and the first recess in the transistor forming region; removing the separation material from the structure; removing from the patterned laminate a portion of the channel material layer disposed at the pattern connection; and filling the space around the plurality of patterned portions with a second separation material; etching a region corresponding to the first vertical hole in the word line material layer to form a through-hole; recessing a portion of the word line material layer exposed through the through-hole such that a first side of the channel material layer protrudes toward the through-hole than the word line material layer to form a recess region; and forming a filling insulating layer within the recess region.

After etching the patterned portion on the capacitor forming region of the structure to form an etching portion, a wet etching solution may be introduced through the etching portion to form the second recess.

The step of defining the protruding channel portion may include the steps of recessing the channel material layer in the second recess; and removing the first and second gate insulating layers from the second recess.

The step of forming the capacitor may include forming an electrode member in contact with the top surface and sides of the first protruding channel portion on an inner surface of the second recess portion; forming a dielectric layer on the electrode member; and forming a plate electrode on the dielectric layer.

After forming the electrode member, the method may further comprise the step of recessing the first insulating layer in the capacitor forming region to expose an outer surface of the electrode member, and after exposing the outer surface of the electrode member, forming the dielectric layer and the plate electrode in sequence.

The first insulating layer, the first sacrificial layer, the first 1-1 gate insulating layer, the channel material layer, the 1-2 gate insulating layer, and the second sacrificial layer may comprise a single unit laminate, and the unit laminate may be repeatedly stacked on the substrate in a step of forming the laminate.

The transistor may be a first transistor, the capacitor may be a first capacitor, and the memory device may be formed to further include a second transistor disposed on the first transistor and a second capacitor disposed on the first capacitor.

According to another embodiment of the present disclosure, includes a plurality of memory cells stacked in a vertical direction, each of the plurality of memory cells includes a transistor and a capacitor electrically connected therewith laterally to the transistor, the transistor including a channel material layer, word lines disposed opposite thereto, and a gate insulating layer disposed therebetween, the capacitor including an electrode member electrically connected with the transistor, a dielectric layer disposed on a surface of the electrode member, and a plate electrode disposed on a surface of the dielectric layer, A memory device is provided, connected to a plurality of transistors of the plurality of memory cells, having a word line extending in a vertical direction, the channel material layer including a protruding channel portion protruding into a capacitor forming region, the electrode member disposed to contact an upper surface and a side surface of the protruding channel portion, the word line including a plurality of gate unit structures spaced apart from each other and a connection line portion connecting the plurality of gate unit structures.

The electrode member may have a structure extending upwardly, downwardly, and laterally with respect to the protruding channel portion while contacting an upper surface and a side of the protruding channel portion, the dielectric layer may be arranged to contact an inner surface and an outer surface of the electrode member, and the plate electrodes may be arranged to contact the dielectric layer while filling an inner space and an outer space of the electrode member.

The plurality of gate unit structures may be disposed between the plurality of bit lines and the plurality of capacitors, and the connecting line portions may have a narrower width than each of the plurality of gate unit structures and may be disposed to connect the plurality of gate unit structures in an extension of the word line.

The plurality of gate unit structures may be disposed on each of two sides of the bit lines, and the connecting line portions may be disposed on each of two sides of the bit lines.

The gate unit structure may have a concave shaped side facing the bit line, when viewed from above.

A sacrificial insulating layer may be disposed between each of the plurality of gate unit structures and the electrode members corresponding thereto, and a separating material membrane comprising a material different from the sacrificial insulating layer may be disposed between the plurality of gate unit structures.

According to embodiments of the present disclosure, a memory device (stacked memory device) capable of increasing integration and securing excellent performance, while being easy to manufacture, and a manufacturing method thereof may be realized. Furthermore, according to embodiments of the present disclosure, a memory device (memory device) and a manufacturing method may be that may low contact resistance and high characteristics by greatly enlarging the contact area between a channel layer and a capacitor and increasing the effective area of a capacitor dielectric layer. Furthermore, according to one embodiment of the present disclosure, by forming a word line comprising a plurality of gate unit structures and a connecting line portion connecting the same, and forming a dual gate structure using a laminate patterned in a predetermined shape, ease of processing may be secured and operation characteristics may be improved. According to one example, the memory device may comprise a horizontally stacked DRAM device.

However, the effects of the present disclosure are not limited to the above effects, and may be variously extended without departing from the technical ideas and scope of the present disclosure.

### BRIEF DESCRIPTION OF THE DRAWINGS

The above and other features and advantages will become more apparent to those of ordinary skill in the art by describing in detail exemplary embodiments with reference to the attached drawings, in which:

FIGS. 1A, 2A, 3A, 4A, 5A, 6A, 7A, 8A, 9A, 10A, 11A, 12A, 13A, 14A, 15A, 16A, 17A, 18A, 19A, 20A, 21A, 22A, and 22A are cross-sectional views to exemplarily illustrate a method of manufacturing a memory device according to one embodiment of the present disclosure.

FIGS. 1B, 2B, 3B, 4B, 5B, 6B, 7B, 8B, 9B, 10B, 11B, 12B, 13B, 14B, 15B, 16B, 17B, 18B, 19B, 20B, 21B, 22B are drawings intended to exemplarily illustrate a method of fabricating a memory device according to one embodiment of the present disclosure.

FIGS. 1C, 2C, 3C, 4C, 5C, 6C, 7C, 8C, 9C, 10C, 11C, 12C, 13C, 14C, 15C, 16C, 17C, 18C, 19C, 20C, 21C, 22C are cross-sectional views to exemplarily illustrate a method of manufacturing a memory device according to one embodiment of the present disclosure.

FIGS. 5D, 6D, 7D, 8D, 9D, 10D, 11D, 12D, 13D, 14D, 15D, 16D, 17D, 18D, 19D, 20D, 21D, 22D are cross-sectional views to exemplarily illustrate a method of fabricating a memory device according to one embodiment of the present disclosure.

FIGS. 22A through 22D are drawings to illustrate a memory device according to one embodiment of the present disclosure.

In the following description, the same or similar elements are labeled with the same or similar reference numbers.

### DETAILED DESCRIPTION

The present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “includes”, “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. In addition, a term such as a “unit”, a “module”, a “block” or like, when used in the specification, represents a unit that processes at least one function or operation, and the unit or the like may be implemented by hardware or software or a combination of hardware and software.

Reference herein to a layer formed “on” a substrate or other layer refers to a layer formed directly on top of the substrate or other layer or to an intermediate layer or intermediate layers formed on the substrate or other layer. It will also be understood by those skilled in the art that structures or shapes that are “adjacent” to other structures or shapes may have portions that overlap or are disposed below the adjacent features.

In this specification, the relative terms, such as “below”, “above”, “upper”, “lower”, “horizontal”, and “vertical”, may be used to describe the relationship of one component, layer, or region to another component, layer, or region, as shown in the accompanying drawings. It is to be understood that these terms are intended to encompass not only the directions indicated in the figures, but also the other directions of the elements.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Preferred embodiments will now be described more fully hereinafter with reference to the accompanying drawings. However, they may be embodied in different forms and should not be construed as limited to the embodiments set forth herein. Rather, these embodiments are provided so that this disclosure will be thorough and complete, and will fully convey the scope of the disclosure to those skilled in the art.

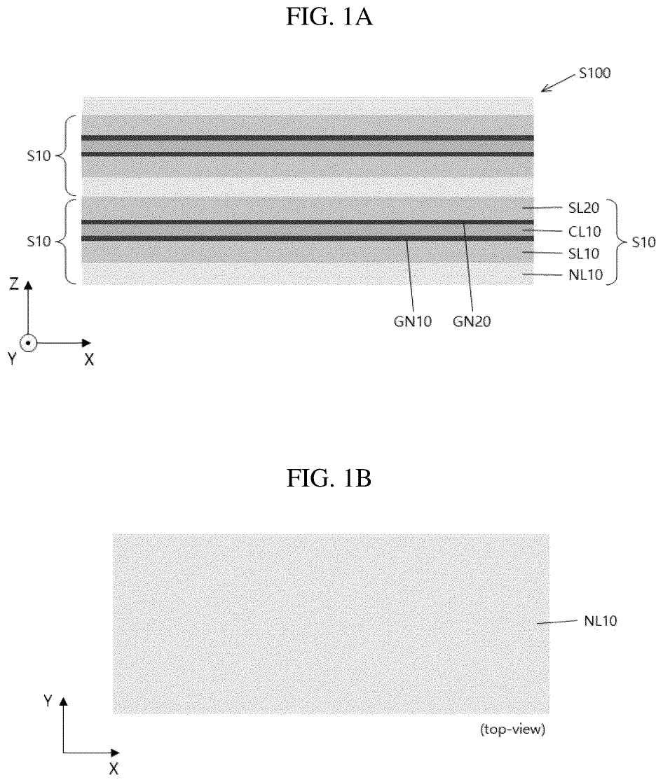

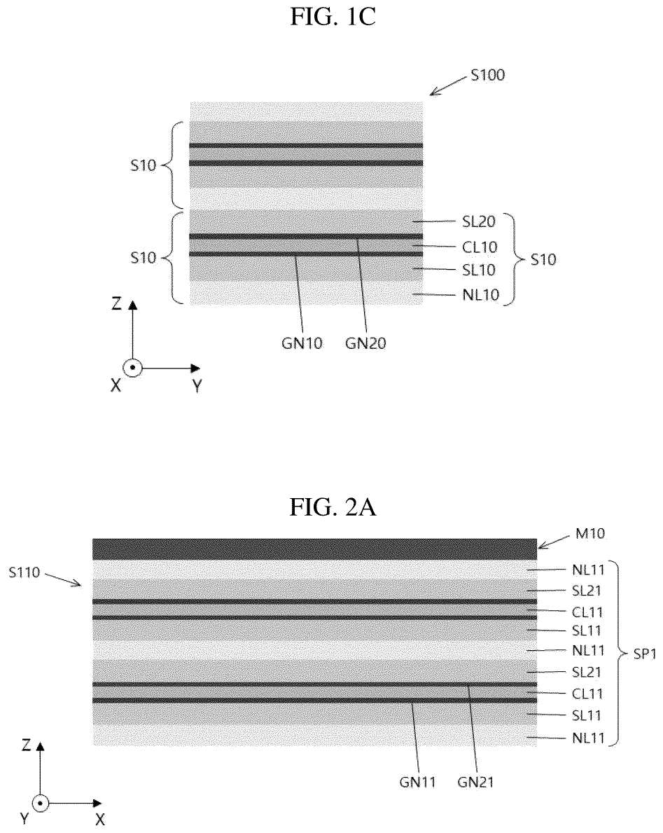

FIGS. 1A through 22D are drawings for exemplarily illustrating a manufacturing method of a memory device (stacked memory device) according to one embodiment of the present disclosure.

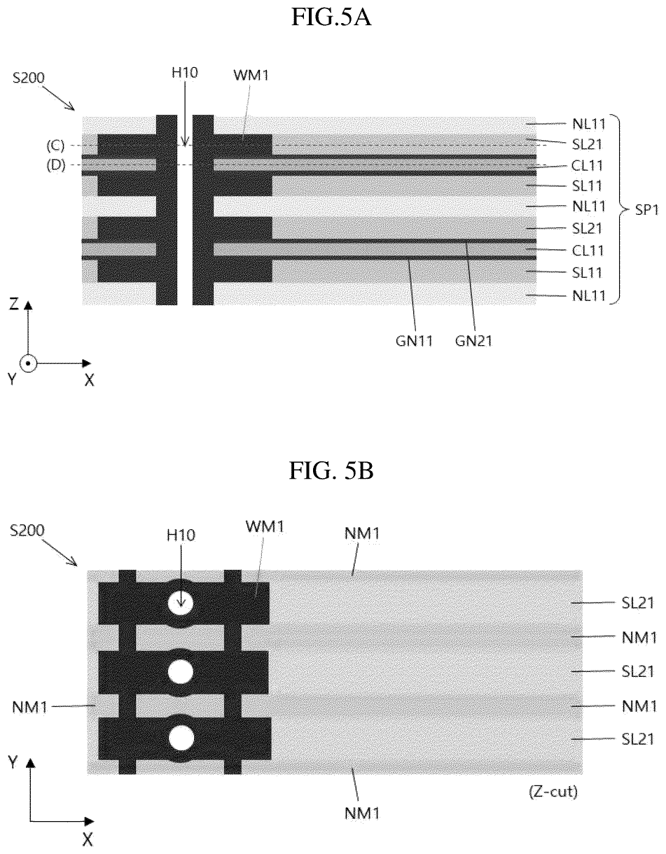

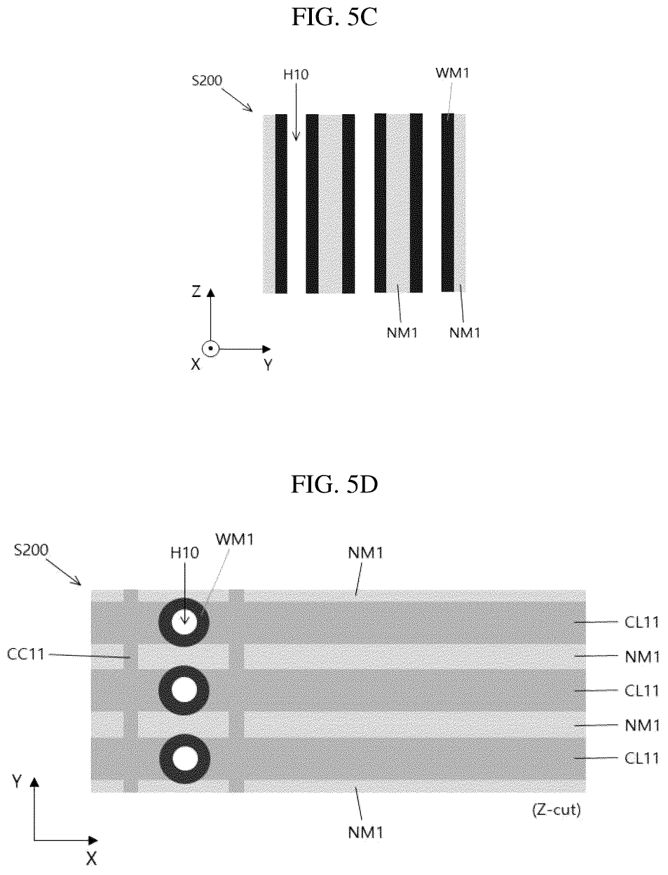

In FIGS. 1A through 22D, the same drawing number (e.g., FIG. 1 in FIG. 1A, FIG. 1B, FIG. 1C) denotes the same step. FIGS. 1A, FIG. 2A, FIG. 3A, FIG. 4A, FIG. 5A, FIG. 6A, FIG. 7A, FIG. 8A, FIG. 9A, FIG. 10A, FIG. 11A, FIG. 12A, FIG. 13A, FIG. 14A, FIG. 15A, FIG. 16A, FIGS. 17A, FIG. 18A, FIG. 19A, FIG. 20A, FIG. 21A, FIG. 22A are cross-sectional views cut in the XZ plane. FIGS. 1B, 2B, 3B, 4B, 5B, 6B, 7B, 8B, 9B, 10B, 11B, 12B, 13B, 14B, 15B, 16B, 17B, 18B, 19B, 20B, 21B, 22B are top views (i.e., top-view) or cross-sectional views (i.e., Z-cut view) cut in the XY plane. FIGS. 1C, 2C, 3C, 4C, 5C, 6C, 7C, 8C, 9C, 10C, 11C, 12C, 13C, 14C, 15C, 16C, 17C, 18C, 19C, 20C, 21C, 22C are cross-sectional views cut in the YZ plane. FIGS. 5D, 6D, 7D, 8D, 9D, 10D, 11D, 12D, 13D, 14D, 15D, 16D, 17D, 18D, 19D, 20D, 21D, 22D are cross-sectional views cut in the XY plane (i.e., Z-cut views).

Referring to FIGS. 1A to 1C, a laminate S100 may be formed on a predetermined substrate (not shown). The material of the substrate may be selected from a variety of materials. The substrate may comprise a semiconductor material or an insulating material. The substrate may comprise a semiconductor wafer. The substrate may include a bulk silicon substrate, a silicon-on-insulator (SOI) substrate, a germanium substrate, a germanium-on-insulator (GOI) substrate, a silicon-germanium substrate, or a substrate formed by an epitaxial growth process.

A laminate S100 may be formed on the substrate. The laminate S100 may include an insulating layer (hereinafter, the first insulating layer) NL10, a first sacrificial layer SL10, a first 1-1 gate insulating layer GN10, a channel material layer CL10, a first 1-2 gate insulating layer GN20, and a second sacrificial layer SL20 stacked in sequence on the first insulating layer NL10. The first insulating layer NL10 may, as a non-limiting example, include or be formed of silicon oxide (e.g., SiO₂). The first sacrificial layer SL10 and the second sacrificial layer SL20 may, as a non-limiting example, comprise or be formed of silicon nitride (e.g., SiNₓ). The first sacrificial layer SL10 and the second sacrificial layer SL20 may have an etch selectivity ratio with respect to the first insulating layer NL10. Further, the first sacrificial layer SL10 and the second sacrificial layer SL20 may have an etch selectivity ratio with respect to the first 1-1 gate insulating layer GN10, the channel material layer CL10, and the second 1-2 gate insulating layer GN20. The first insulating layer NL10, the first sacrificial layer SL10, the first 1-1 gate insulating layer GN10, the channel material layer CL10, the first 1-2 gate insulating layer GN20, and the second sacrificial layer SL20 may be formed by a deposition process. The first insulating layer NL10, the first sacrificial layer SL10, the first 1-1 gate insulating layer GN10, the channel material layer CL10, the first 1-2 gate insulating layer GN20, and the second sacrificial layer SL20 may all be material layers formed in a horizontal direction.

The first gate insulating layer GN10 and the second gate insulating layer GN20 may be formed to include at least one of a silicon oxide, a silicon nitride, a silicon nitride, and a high-k material. Here, the high-k material may be a material having a higher dielectric constant than the silicon nitride. The specific material of the gate insulation material layer GN1 is not limited to the above, but may be varied. The channel material layer CL10 may include an oxide semiconductor or a non-oxide semiconductor. The oxide semiconductor may include an amorphous oxide semiconductor (AOS). The oxide semiconductor may include at least one selected from the group consisting of, for example, indium gallium zinc oxide (IGZO), zinc tin oxide (ZTO), indium tin oxide (ITO), and the like. The channel material layer CL10 may be configured to include a polycrystalline semiconductor or an amorphous semiconductor. The channel material layer CL10 may also be configured to include silicon, germanium, or silicon-germanium. However, the specific material of the channel material layer CL10 is not limited to the above, and may be varied. The channel material layer CL10 may be monolayer or multilayer.

According to one embodiment, the first insulating layer NL10, the first sacrificial layer SL10, the first 1-1 gate insulating layer GN10, the channel material layer CL10, the first 1-2 gate insulating layer GN20, and the second sacrificial layer SL20 may comprise one unit laminate S10, and the unit laminate S10 may be repeatedly stacked on the substrate in a step of forming the laminate S100. Thus, the laminate S100 may comprise a plurality of repeatedly stacked unit laminates S10. In FIGS. 1A and 1C, two unit laminates S10 are stacked on the substrate and a first insulating layer NL10 is further formed thereon, but the number of unit laminates S10 stacked may be more than two.

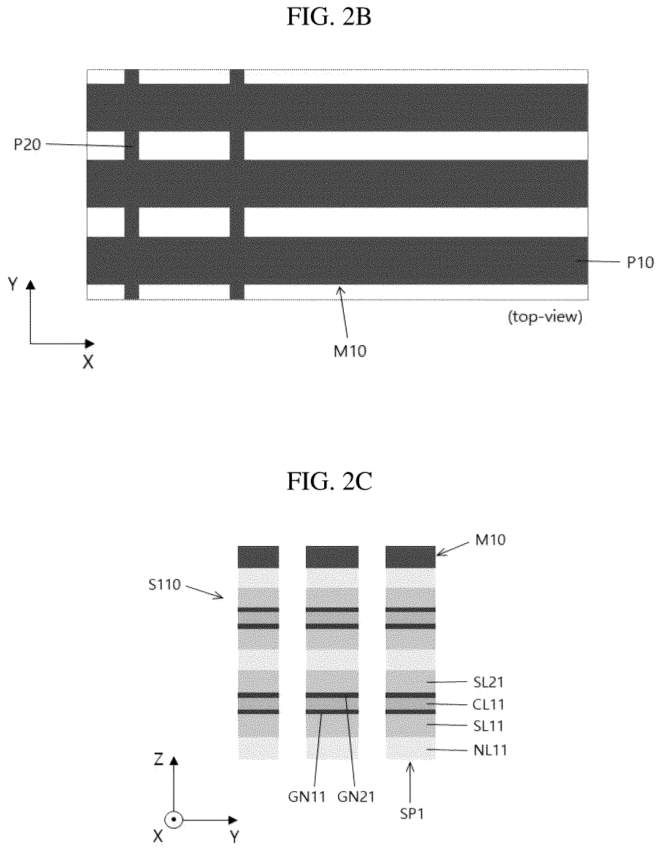

Referring to FIGS. 2A to 2C, the laminate (S100 in FIG. 1A) may be patterned to form a patterned laminate S110 having at least one patterned portion SP1. The patterned portion SP1 may have a shape extending in a first direction, for example, in the X-axis direction, and may be provided with etched regions (etched blank regions) on both sides of the patterned portion SP1 along a second direction perpendicular to the first direction, for example, in the Y-axis direction. The plurality of patterned portions SP1 may be spaced apart in the Y-axis direction and may be arranged next to each other in the X-axis direction. This step may be a patterning step for separation between cells.

The patterned portion SP1 may include a patterned first insulating layer NL11, a patterned first sacrificial layer SL11, a patterned first 1-1 gate insulating layer GN11, a patterned channel material layer CL11, a patterned first 1-2 gate insulating layer GN21, and a patterned second sacrificial layer SL21. The patterned first insulating layer NL11, the patterned first sacrificial layer SL11, the patterned first 1-1 gate insulating layer GN11, the patterned channel material layer CL11, the patterned first 1-2 gate insulating layer GN21, and the patterned second sacrificial layer SL21 may be referred to as a first insulating layer pattern, a first sacrificial layer pattern, a first 1-1 gate insulating layer pattern, a channel material layer pattern, a first 1-2 gate insulating layer pattern, and a second sacrificial layer pattern, respectively.

For the patterning process of FIGS. 2A to 2C, a first mask pattern M10 disposed on the laminate (S100 in FIG. 1A) may be used. The first mask pattern M10 may have a predetermined pattern structure. The first mask pattern M10 may be, for example, a photoresist pattern. After the above patterning process, the first mask pattern M10 may be removed.

According to one embodiment, the patterned laminate S110 may be formed to include a plurality of patterned portions SP1 mutually spaced apart in the second direction (e.g., in the Y-axis direction) and a “pattern connection” connecting the plurality of patterned portions SP1 in the second direction (e.g., in the Y-axis direction). To this end, as shown in FIG. 2B, the first mask pattern M10 may include a plurality of first mask portions P10 spaced apart from each other in the second direction (e.g. Y-axis direction) and a second mask portion P20 for connecting the plurality of the first mask portions P10 in the second direction (e.g. the Y-axis direction). The plurality of first mask parts P10 may have a shape (e.g., a line shape) extending in the first direction (e.g., an X-axis direction), and the second mask part P20 for connecting may have a shape (e.g., a line shape) extending in the second direction (e.g., a Y-axis direction). The second mask portion P20 for connecting may be arranged to form a plurality of lines, and may be arranged to form two lines in the illustrated example. The plurality of patterned portions SP1 of the patterned laminate S110 may be formed to correspond to the plurality of first mask portions P10, and the patterned connection portions of the patterned laminate S110 may be formed to correspond to the second mask portions P20 for connection. The patterned connection portion of the patterned laminate S110 may be a portion for later forming a connection portion (connection line portion) of a word line.

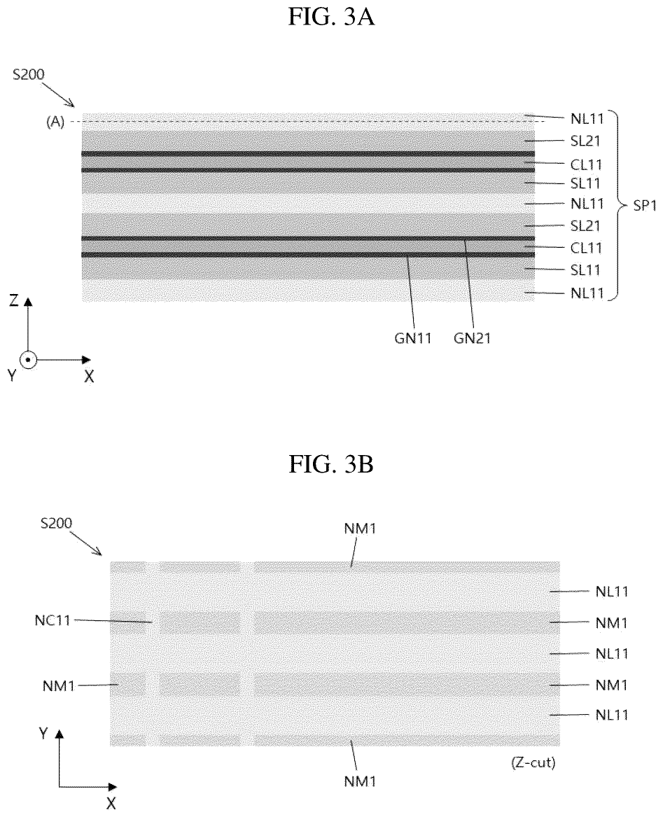

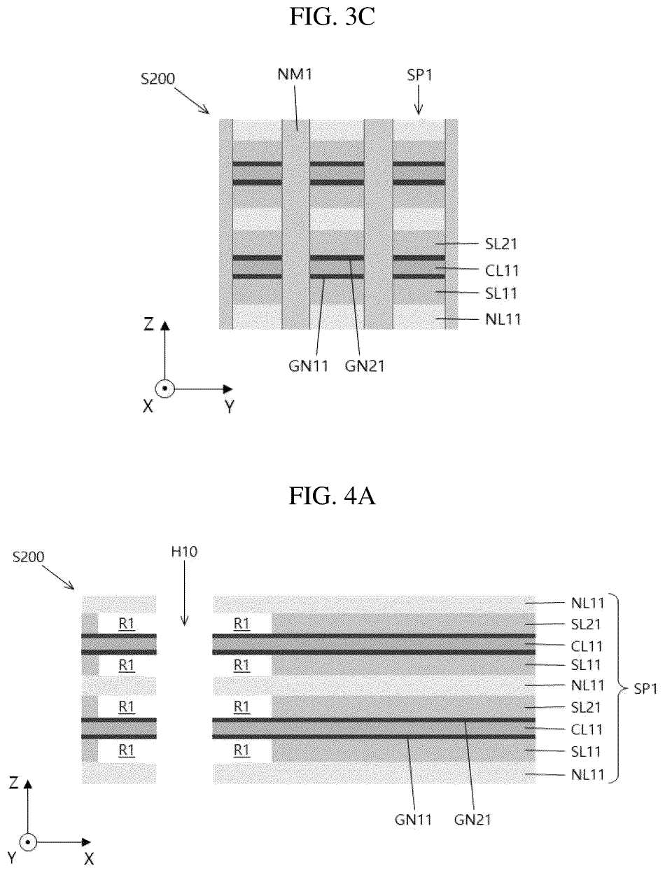

Referring to FIGS. 3A to 3C, a structure S200 comprising at least the patterned laminate S110 of FIG. 2A may be formed by filling the etched areas (etched hollow areas) on both sides of at least one patterned part SP1 with the separation material NM1. A structure S200 comprising the patterned laminate (S110 of FIG. 2A) and the separation material (M1) may be formed. Here, FIG. 3B may be a cross-sectional view along line (A) of FIG. 3A.

The separation material NM1 may be referred to as a “separation material layer” or “separation material layer pattern” or “separation membrane” and may have the same (or substantially the same) height as the patterned portion SP1. The separating material NM1 may have a different material composition than the first insulating layer NL11 and the first and second sacrificial layers SL11, SL21. In other words, the separation material NM1 may have a different material composition than the first insulating layer NL10 and the first and second sacrificial layers SL10, SL20 of FIG. 1A. The first insulating layer NL11 may have an etch selectivity with respect to the separation material NM1, and the first and second sacrificial layers SL11, SL21 may also have an etch selectivity with respect to the separation material NM1. The separation material NM1 may be, but is not limited to, an insulating material.

In FIG. 3B, reference numeral NC11 indicates a first insulating layer pattern connection (a kind of extension) corresponding to the above-described “pattern connection”.

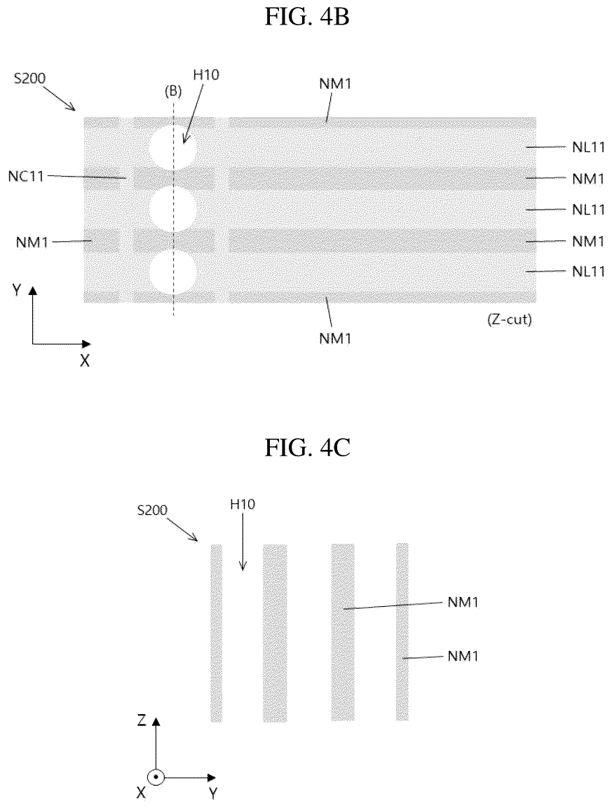

Referring to FIGS. 4A to 4C, a first vertical hole H10 through the patterned portion SP1 may be formed in the structure S200. The first vertical hole H10 may be formed to penetrate from the first insulating layer NL11 of the uppermost part of the pattern part SP1 to the first insulating layer NL11 of the lowermost part in a predetermined region of the structure S200. The first vertical hole H10 may correspond to a region where a bit line is to be formed later. The first vertical hole H10 may be formed in a region where a transistor is to be formed in the structure S200, that is, a transistor formation region (transistor formation region to be formed). The plurality of first vertical holes H10 may be spaced apart from each other in the Y-axis direction. The first vertical hole H10 may be formed by a dry etch process. FIG. 4C may be a cross-sectional view along line (B) of FIG. 4B.

According to one embodiment, the “patterned connections” may be arranged to form two mutually adjacent lines, and a first vertical hole H10 may be formed between the two lines.

After forming the first vertical hole H10, the first and second sacrificial layers SL11, SL21 around the first vertical hole H10 may be recessed to form the first recess portion R1. The first and second sacrificial layers SL11, SL21 may be selectively recessed using a wet etch process utilizing a wet etch solution having etch selectivity on the first and second sacrificial layers SL11, SL21. The wet etch solution may be introduced through the first vertical hole H10, and the first and second sacrificial layers SL11, SL21 exposed by the first vertical hole H10 may be recessed. At this time, the first sacrificial layer pattern connection (a kind of extension) and the second sacrificial layer pattern connection (a kind of extension) corresponding to the above-mentioned “pattern connection” may also be recessed and removed. Since the separation material NM1 has an etch selectivity ratio with the sacrificial layers SL11, SL21, it may not be removed.

Referring to FIGS. 5A to 5D, a material layer WM1 for the word line may be formed that fills at least a portion of the first vertical hole H10 while filling the first recess R1 of FIG. 4A. The material layer WM1 for the word line may completely fill the first recess (R1 in FIG. 4A). Also, the material layer WM1 for the word line may be formed on an inner surface of the first vertical hole H10 and may not completely fill the first vertical hole H10. However, in some cases, the material layer WM1 for the word line may completely fill the first vertical hole H10. Furthermore, the material layer WM1 for the word line may also be formed in a space where the first sacrificial layer pattern connection and the second sacrificial layer pattern connection corresponding to the “pattern connection” described above are removed, and the portion of the material layer WM1 for the word line formed in this space may a line shape extending in the Y-axis direction. FIG. 5B may be a cross-sectional view along line (C) of FIG. 5A, and FIG. 5D may be a cross-sectional view along line (D) of FIG. 5A, that is, FIG. 5B may be a cross-sectional view at a word line level (height), and FIG. 5D may be a cross-sectional view at a channel layer level (height).

The word line material layer WM1 may be formed substantially conformally to the shape of the exposed surface areas in the transistor formation region. The material layer WM1 for the word line may be formed (deposited), for example, by an ALD process. The material layer WM1 for the word line may comprise a metal or a metal compound.

In FIG. 5D, reference numeral CC11 indicates a channel material layer pattern connection (a kind of extension) corresponding to the above-described “pattern connection”.

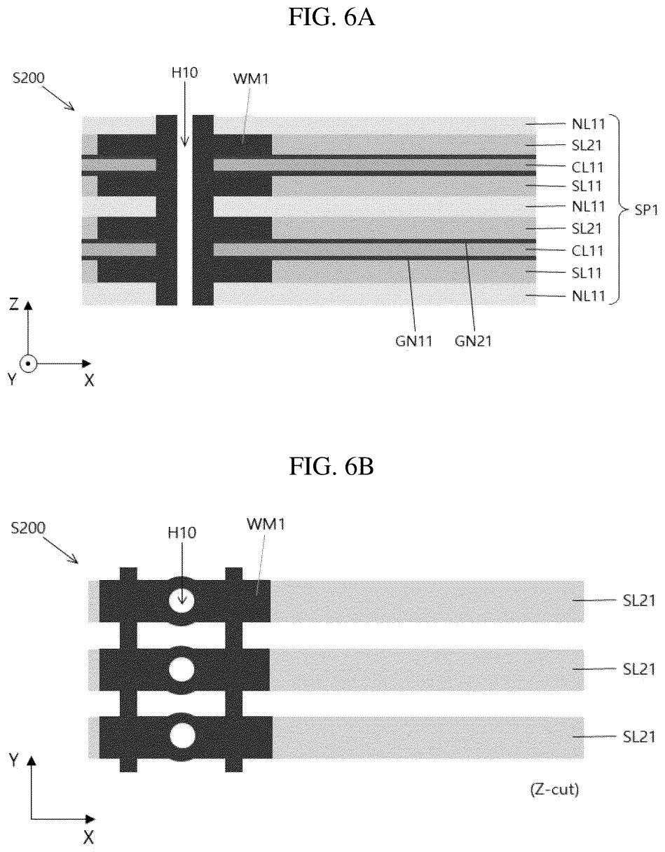

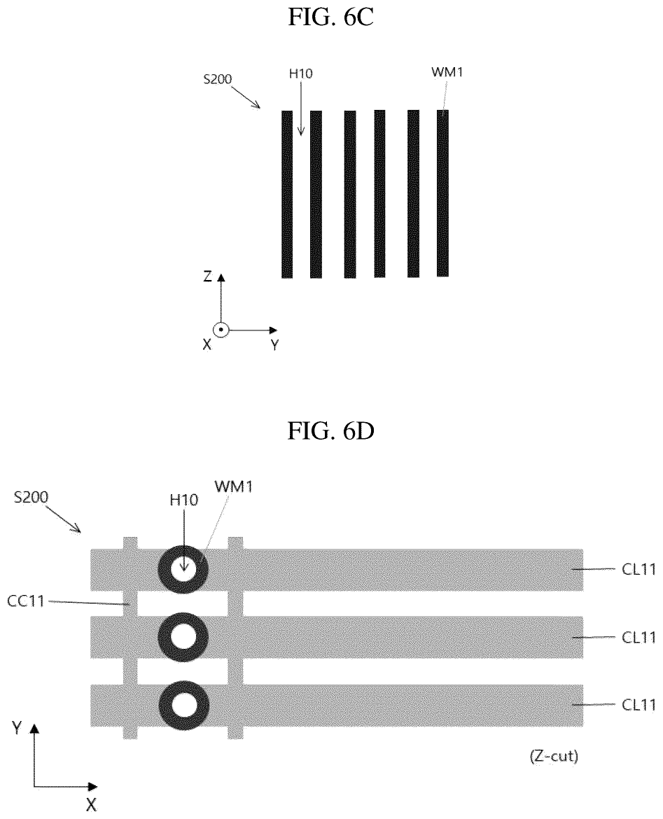

Referring to FIGS. 6A to 6D, the separation material (M1 of FIGS. 5B to 5D) may be removed from the structure S200. For example, the separation material (M41 of FIGS. 5B to 5D) may be selectively removed by utilizing a wet etching process having etching selectivity on the separation material (M1 of FIGS. 5B to 5D). The process of removing the separation material may be referred to as a separator strip.

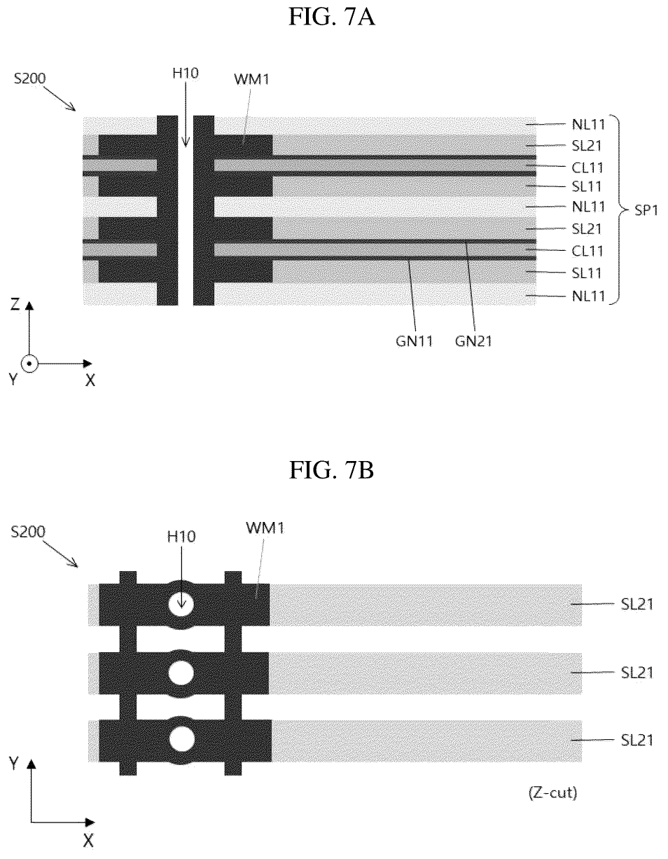

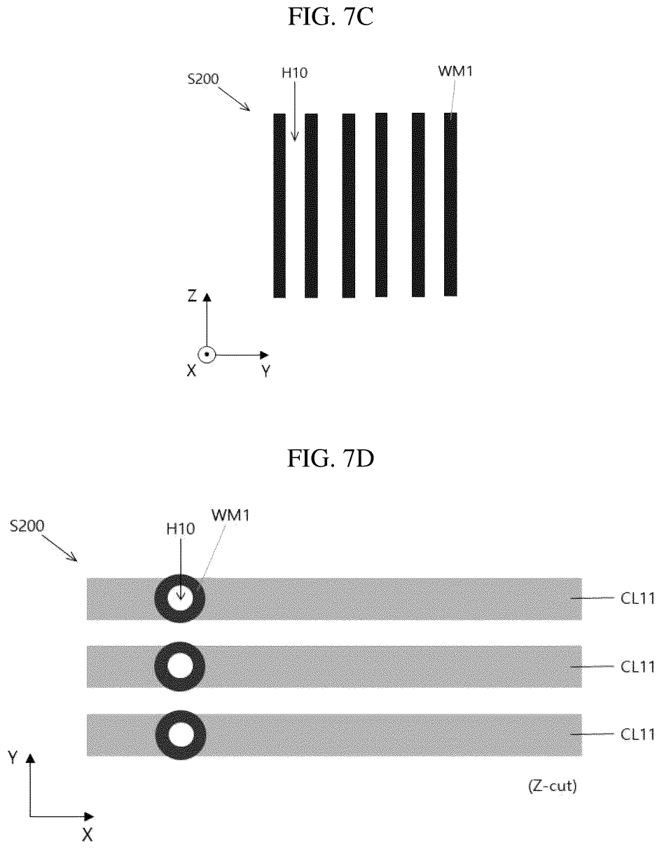

Referring to FIGS. 7A to 7D, in the patterned laminate, a portion of the channel material layer CL11 disposed at the ‘pattern connection’ may be removed (compare FIGS. 6D and 7D). By recessing and removing the portion of the channel material layer CL11 disposed corresponding to the “pattern connection” from the structure S200, that is, the channel material layer pattern connection CC11, the connection portion of the channel material layer CL11 may be disconnected. Since the portion of the channel material layer CL11 disposed in the “pattern connection”, i.e., the channel material layer pattern connection CC11, may have a relatively small width, it is possible to remove this portion using a wet etching process. At this time, the main body portion of the channel material layer CL11 may also be slightly etched.

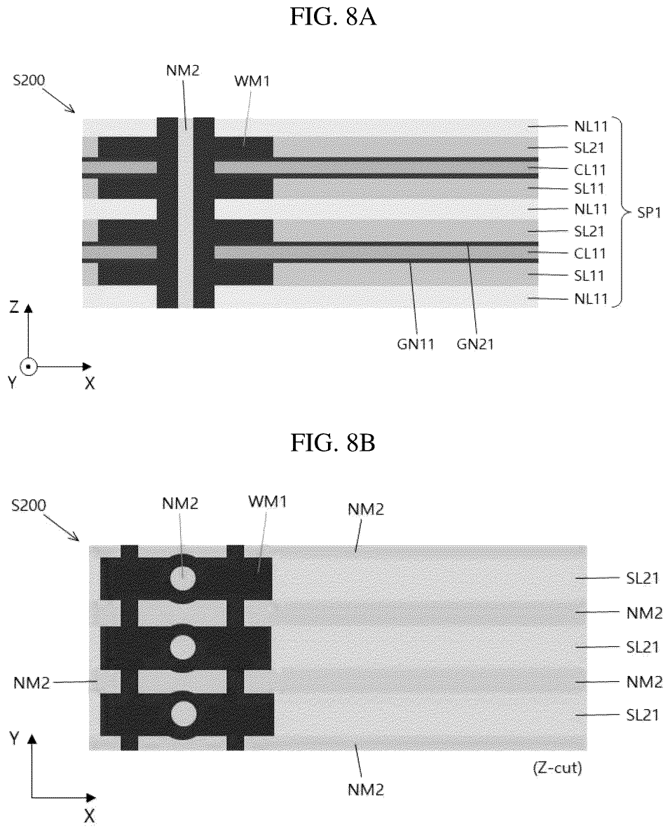

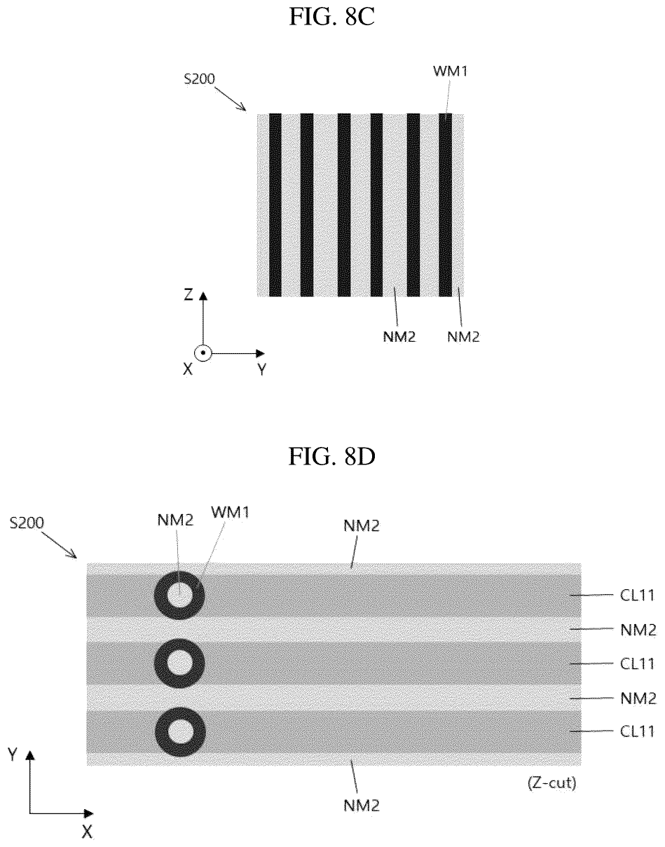

Referring to FIGS. 8A to 8D, the space around the patterned portion SP1 may be filled with a second separation material (M42). The space around the plurality of patterned portions SP1 may be filled with the second separation material NM2. The second separation material NM2 may be formed, for example, but not limited to, by an ALD process. The second separation material NM2 may be filled in the space on both sides of the plurality of patterned parts SP1 and the surrounding space of the material layer WM1 for the word lines.

The second separating material NM2 may be referred to as a “separating material layer” or “separating material layer pattern” or “separator” and may have the same (or substantially the same) height as the patterned portion SP1. The second separating material NM2 may have a different material composition than the first insulating layer NL11 and the first and second sacrificial layers SL11, SL21. In other words, the second separation material NM2 may have a different material composition than the first insulating layer NL10 and the first and second sacrificial layers SL10, SL20 of FIG. 1A. The first insulating layer NL11 may have an etch selectivity with respect to the second separation material NM2, and the first and second sacrificial layers SL11, SL21 may have an etch selectivity with respect to the second separation material NM2. The second separation material NM2 may be, but is not limited to, an insulating material. The second separation material NM2 may be the same material as the separation material NM1 of FIG. 3, but may also be a different material.

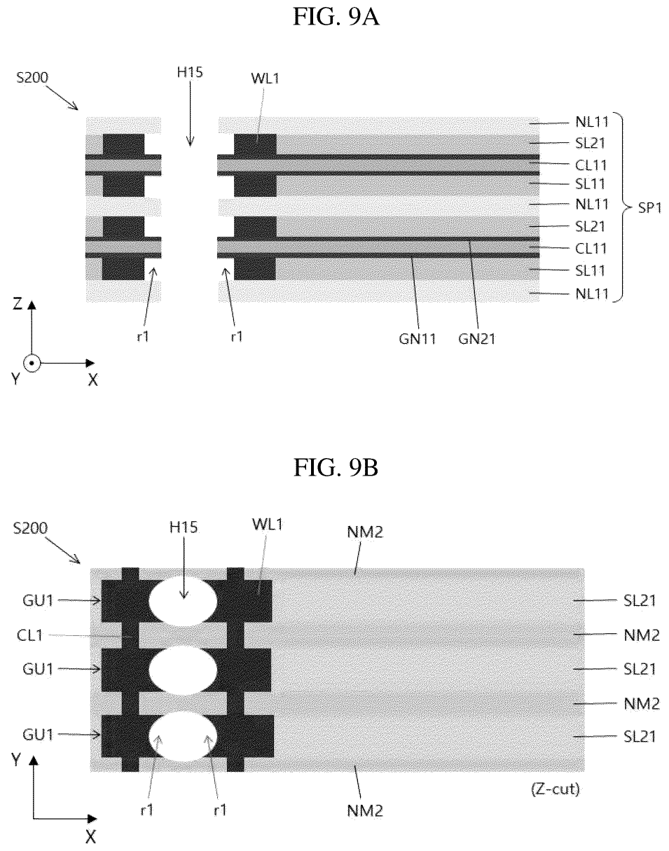

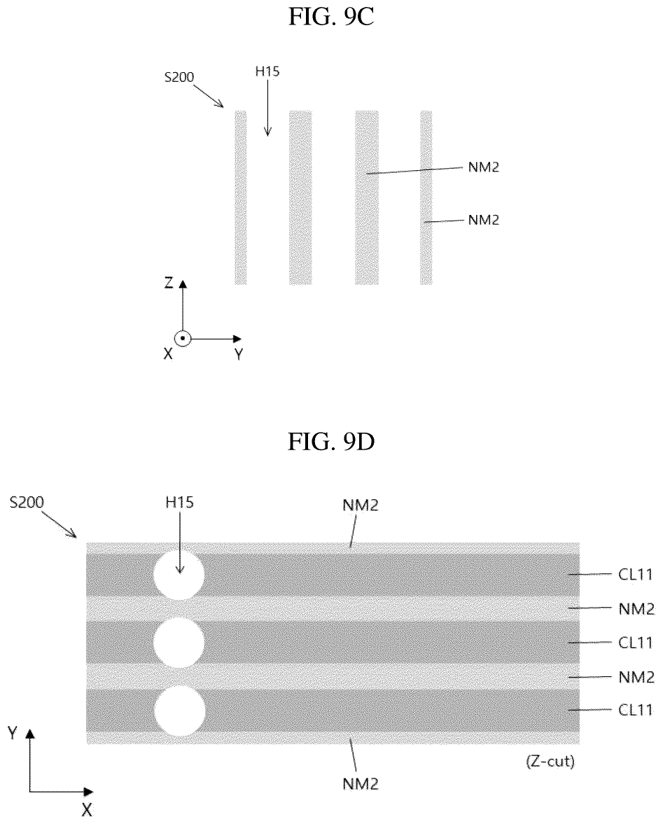

Referring to FIGS. 9A to 9D, the through hole H15 may be formed by etching a region corresponding to the first vertical hole (H10 of FIG. 4A) in the word line material layer (WM1 of FIG. 8A). For example, using a dry etching process, a portion of the material layer for the word line (WM1 in FIG. 8A) and a portion of the second separation material (M42) formed inside the first vertical hole (H10 in FIG. 4A) may be removed by etching.

Then, a portion of the material layer for the word line (WM1 in FIG. 8A) exposed through the through hole H15 may be recessed to form the recess region r1 such that a first side of the channel material layer CL11 protrudes toward the through hole H15 than the material layer for the word line (WM1 in FIG. 8A). As the recess region r1 is formed, the through hole H15 may be enlarged to some extent on both sides along the X-axis direction in the region where the material layer for the word line (WM1 in FIG. 8A) is formed. The first 1-1 gate insulating layer GN11 and the second 1-2 gate insulating layer GN21 disposed on the lower and upper surfaces of the channel material layer CL11 may be exposed by the recess region r1.

A word line WL1 may be formed from the material layer for the word line (WM1 in FIG. 8A), and a transistor comprising the word line WL1 may be defined.

According to one embodiment, the word line WL1 may include a gate unit structure GU1 formed in response to the channel material layer CL11 of the transistor forming region. The plurality of gate unit structures (GU1) may be spaced apart from each other in the second direction (e.g., the Y-axis direction), and the word line (WL1) may further include a connection line portion (CL1) connecting the plurality of gate unit structures (GU1) in the second direction (e.g., the Y-axis direction). The connection line portion CL1 may be formed at a position corresponding to the “pattern connection portion” described above. The connection line portion CL1 may also be referred to as a “gate pattern connection portion” or a “connection pattern portion”. The connection line portion CL1 may be arranged to form a plurality of lines. For example, the connection line portion CL1 may be arranged to form two lines, and the through hole H15 may be located between the two lines.

Further, according to one embodiment, the word line WL1 may have a dual gate structure. With respect to a region of the one channel material layer CL11 corresponding to one channel, a first gate layer and a second gate layer may be disposed on the lower and upper sides thereof, respectively, and the first and second gate layers may constitute a dual gate structure. By the dual gate structure, gate control may be improved.

However, the specific method of forming the word line WL1 described above is exemplary and may be varied in some cases.

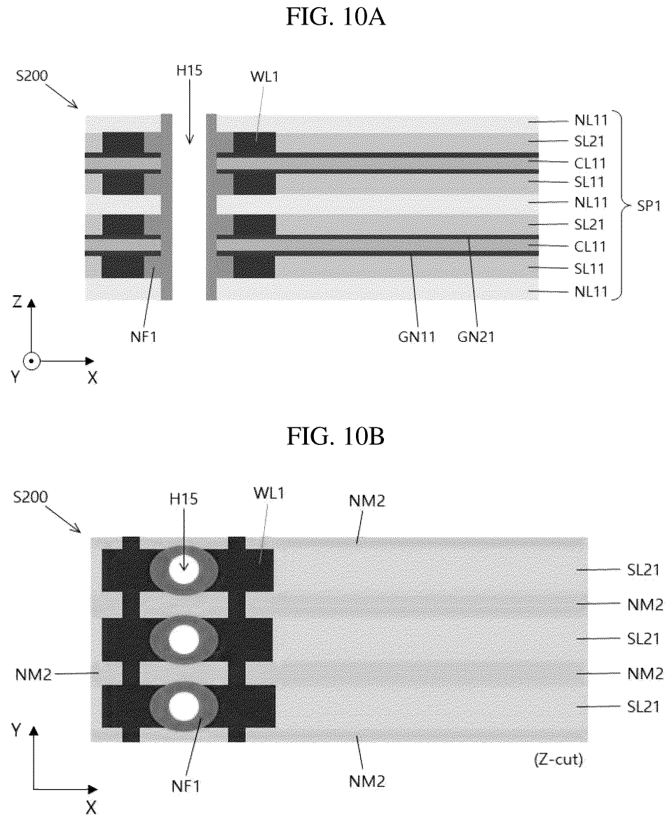

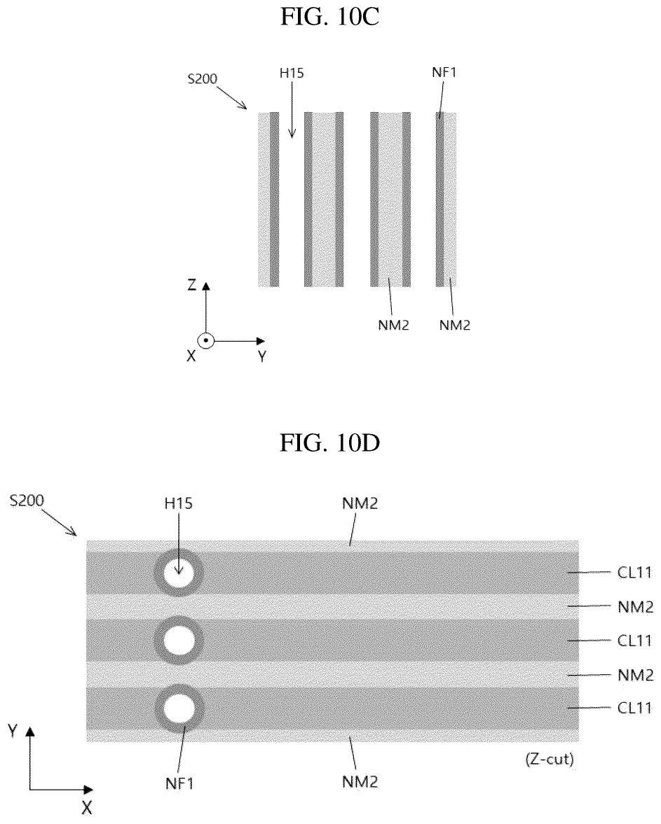

Referring to FIGS. 10A to 10D, a filling insulating layer NF1 may be formed that fills at least a portion of the through-hole H15 while filling the interior of the recess region (r1 in FIG. 9A). The filling insulating layer NF1 may be formed (deposited), for example, by an ALD process, but is not limited thereto.

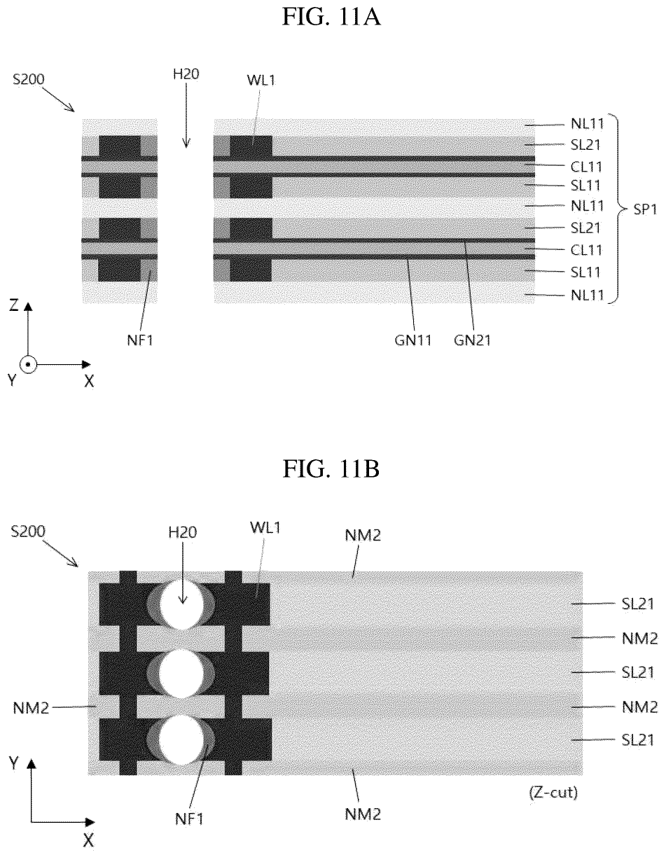

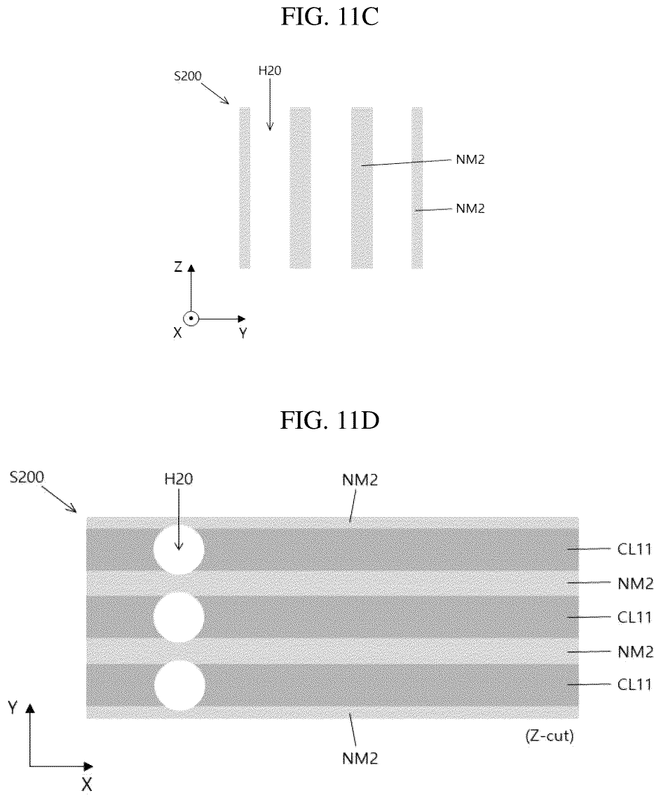

Referring to FIGS. 11A to 11D, a second etch hole H20 may be formed by etching a region corresponding to the first vertical hole (H10 in FIG. 4A) in the filled insulating layer NF1. For example, a portion of the filled insulating layer NF1 formed on the inside of the through hole H15 (H15 in FIG. 10A) may be removed by etching using a dry etching process. A portion of the filled insulating layer (NF1) formed on the side wall of the through hole (H15) (H15 in FIG. 10A) may be removed. A second etching hole H20 corresponding to the first vertical hole (H10 in FIG. 4A) may be formed.

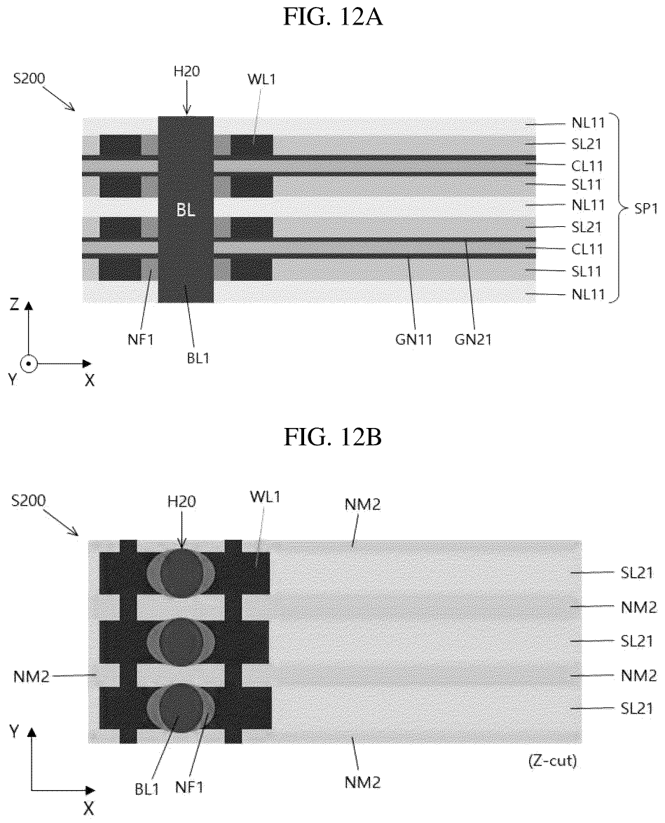

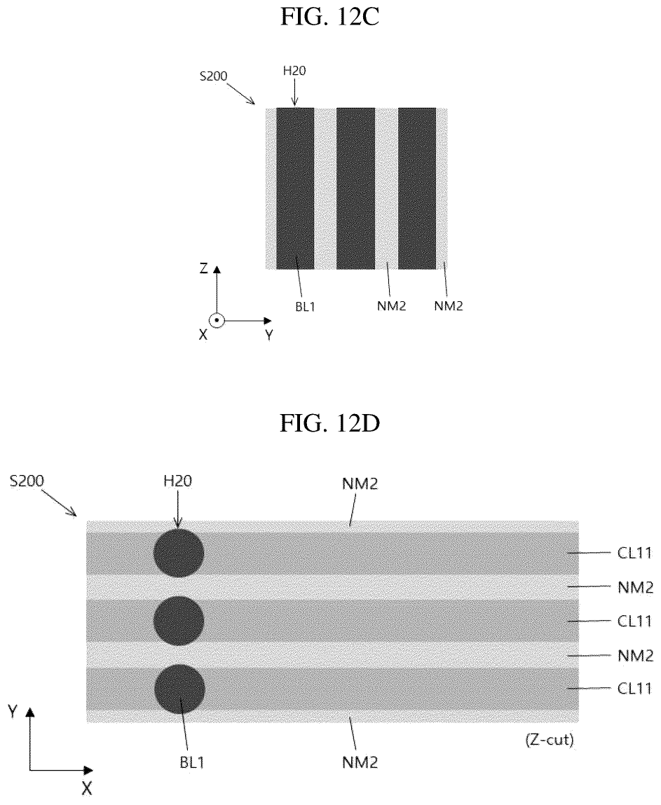

The filling insulation layer NF1 remaining inside the recess region (r1 in FIG. 9A) may serve to separate the word line WL1 from the bit line BL1 in FIG. 12A that will be formed thereafter.

Referring to FIGS. 12A to 12D, a bit line BL1 may be formed in the second vertical hole H20. The bit line BL1 may be the to be formed in a region corresponding to the first vertical hole (H10 in FIG. 4A). The bit line BL1 may be connected (contacted) to one side of the channel material layer CL11 corresponding to the channel of the transistor. The bit line BL1 may have the shape of a pillar that vertically penetrates the structure S200 formed on the substrate. The bit line BL1 may be electrically connected to an end of the channel material layer CL11 in a lateral direction. A plurality of bit lines BL1 connected to a plurality of channel material layers CL11 may be formed.

Although not shown, if there is any conductive material on the bit line BL1 deposited on top of the second vertical hole H20, it may be removed, for example, by an etchback process.

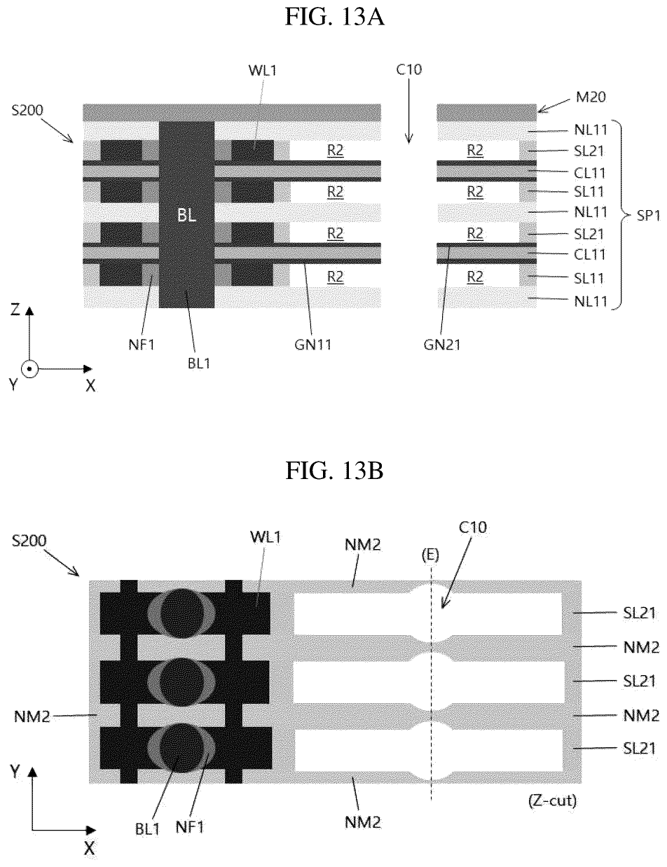

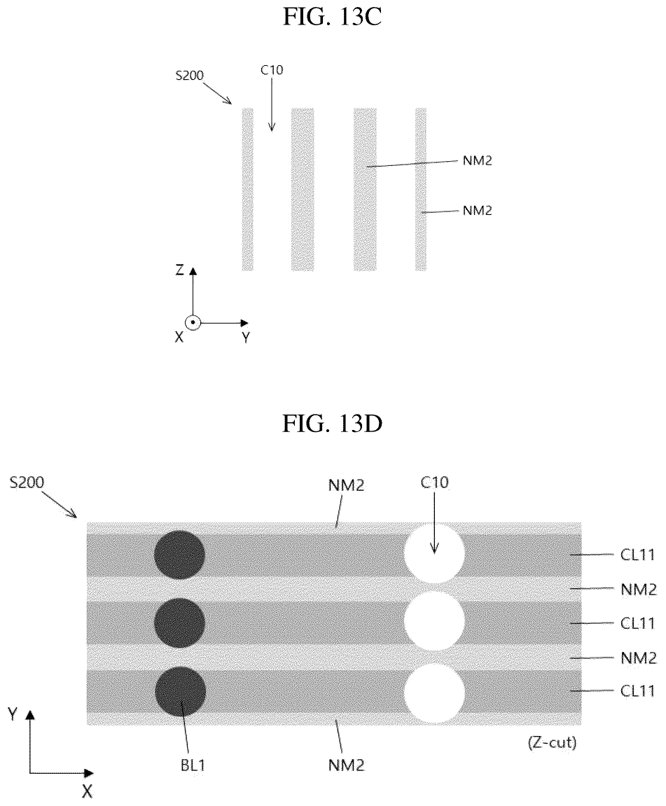

Referring to FIGS. 13A to 13D, a first etch portion C10 spaced apart from the word line WL1 may be formed in the structure S200. The first etching portion C10 may be formed in the capacitor forming region adjacent to the transistor forming region (transistor forming region) and the capacitor forming region (capacitor forming region) in the structure S200. The first etching portion C10 may have a vertical hole structure. The first etching portion C10 may have a vertical hole structure that penetrates the patterned portion SP1 in the capacitor forming region. A plurality of first etching portions C10 may be formed, each penetrating the plurality of patterned portions SP1. The first etching part C10 may be formed to penetrate from the first insulating layer NL11 of the uppermost part of the pattern part SP1 to the first insulating layer NL11 of the lowermost part. The first etching portion C10 may be formed by a dry etching method. The first etch portion (C10) may be referred to as a first capacitor area hole.

For the formation of the first etching portion C10, a second mask pattern M20 may be used. The second mask pattern M20 may have a predetermined opening area. The second mask pattern M20 may be, for example, a hard mask pattern. The hard mask pattern may be formed of, for example, but not limited to, a polycrystalline material.

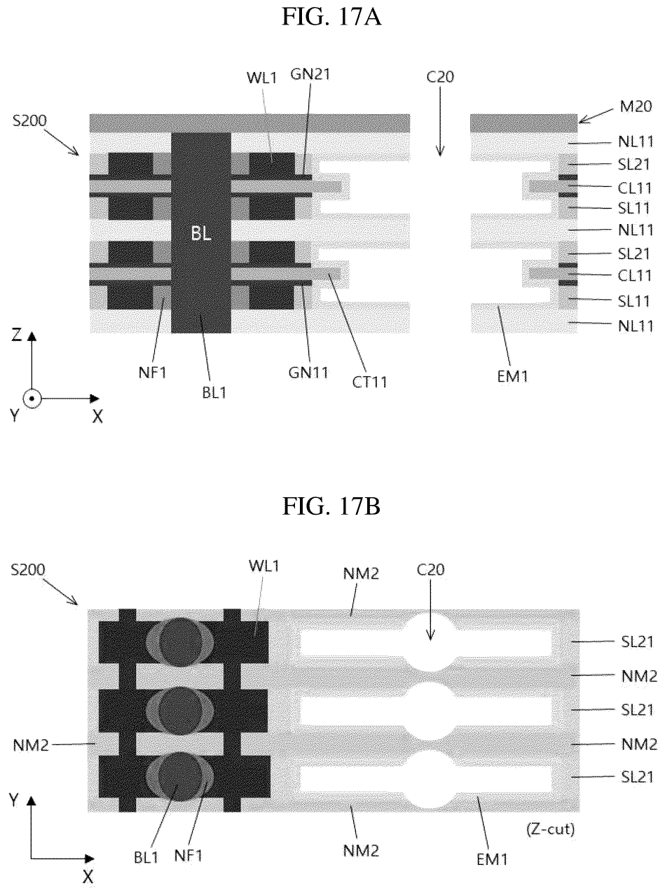

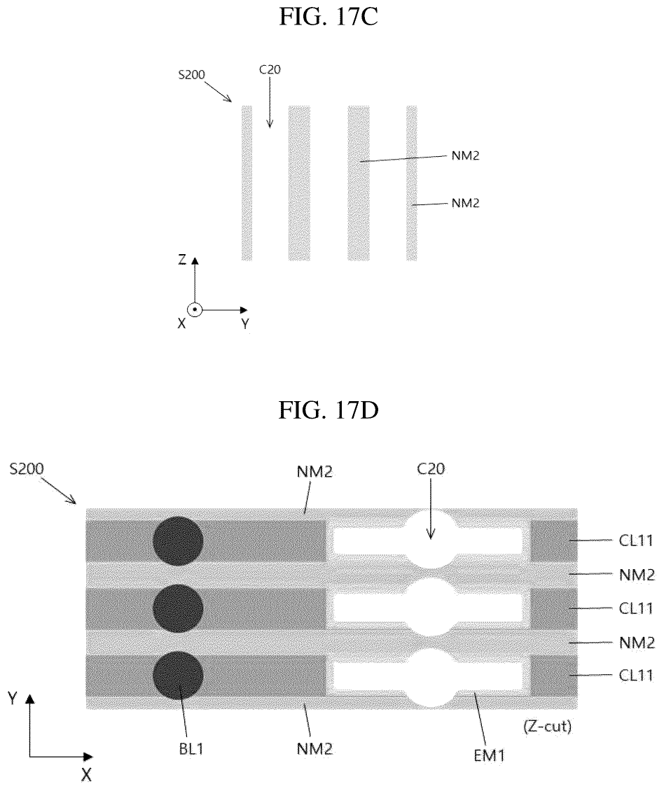

Next, the first and second sacrificial layers SL11, SL21 may be recessed in the capacitor forming region (capacitor forming region to be formed) of the structure 200 to form a second recess portion R2 to expose the first and second gate insulating layers GN11, GN21. A wet etch solution having etch selectivity for the first and second sacrificial layers SL11, SL21 may be injected through the first etch part C10 to selectively recess the first and second sacrificial layers SL11, SL21. At this time, a portion of the first and second sacrificial layers SL11, SL21 may be retained for separation (insulation) between the word line WL1 and the capacitor electrode (i.e., EM1 in FIG. 17A) to be formed later. By controlling the conditions of the wet etch process, a portion of the first and second sacrificial layers SL11, SL21 may be retained.

Referring to FIGS. 14A to 14D, the channel material layer CL11 exposed by the first etching part C10 in the capacitor formation area (capacitor formation area to be formed) may be recessed. In other words, the channel material layer CL11 may be recessed in the second recess part R2. The channel material layer CL11 may be selectively recessed by injecting a wet etching solution having etching selectivity for the channel material layer CL11 through the first etching part C10. At this time, a portion of the channel material layer CL11 may be retained in the capacitor formation region such that the channel material layer CL11 has a structure protruding into the capacitor formation region.

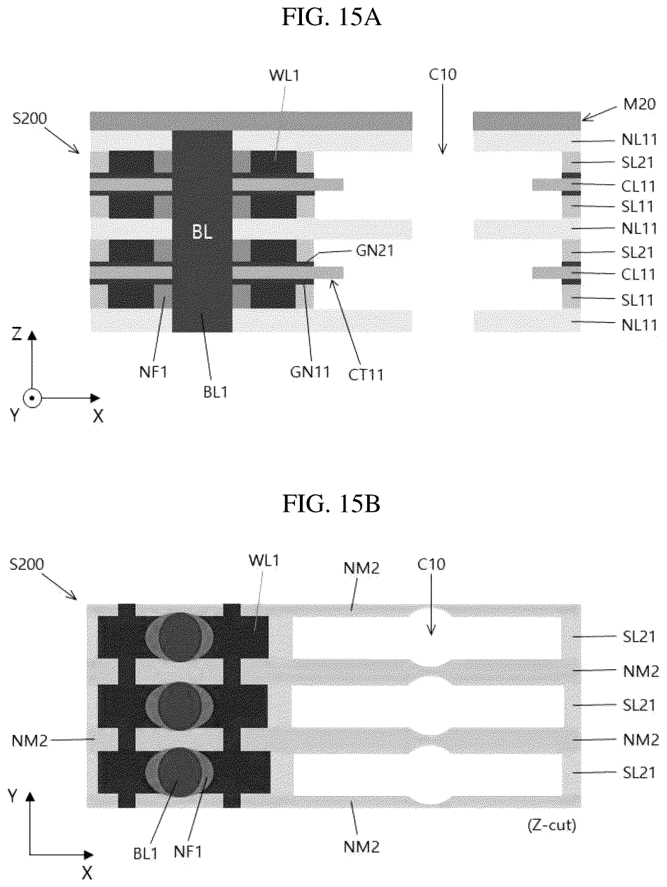

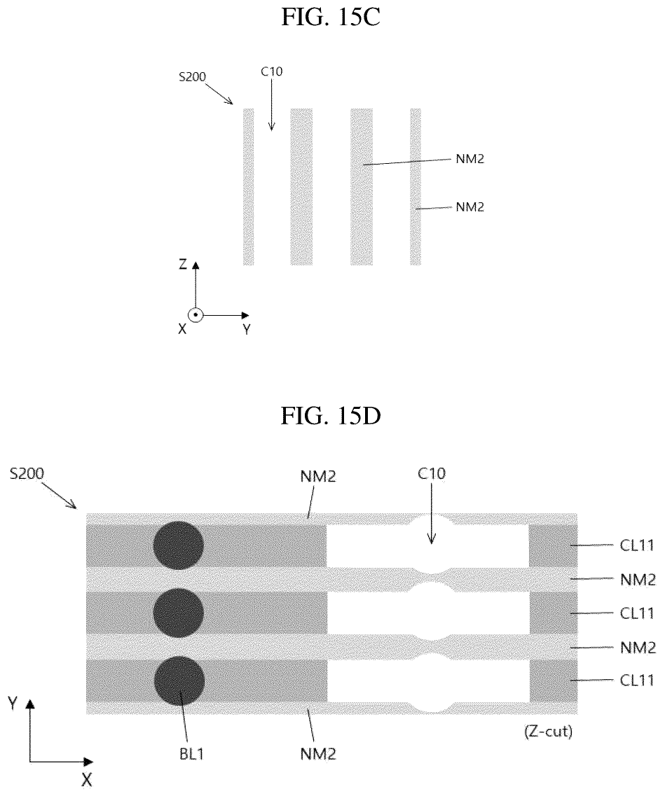

Referring to FIGS. 15A to 15D, the first 1-1 and first 1-2 gate insulating layers GN11, GN21 exposed by the first etching portion C10 in the capacitor forming region (capacitor forming region to be formed) may be recessed. In other words, the first 1-1 and first 1-2 gate insulating layers GN11, GN21 may be removed by recessing the second recess portion R2. Through the first etching part C10, a wet etching solution having etching selectivity for the first 1-1 and second gate insulating layers GN11, GN21 may be injected to selectively recess the first 1-1 and second gate insulating layers GN11, GN21. The first 1-1 and second 1-2 gate insulating layers (GN11, GN21) may be removed from the capacitor forming region.

In FIG. 15A, the protruding channel portion CT11 protruding into the capacitor forming region may be retained. In other words, the protruding channel portion CT11 protruding into the second recess R2 may be retained. The top surface and sides of the protruding channel portion CT11 may be exposed. The protruding channel portion CT11 may have a patterned layer shape extending from the remainder of the channel material layer CL11. As a non-limiting example, the protruding length of the protruding channel portion CT11 may be about 20˜50% of the length in the horizontal direction (x-axis direction in the drawing) of the electrode member EM1 in FIG. 17A formed in the step of FIG. 17A. For example, the protruding length of the protruding channel portion CT11 may be about 15˜45 nm, but is not limited thereto. Depending on the length of the electrode member (EM1 in FIG. 17A) formed in the step of FIG. 17A in the horizontal direction (x-axis direction in the drawing), or depending on other conditions, the protruding length of the protruding channel portion CT11 may vary.

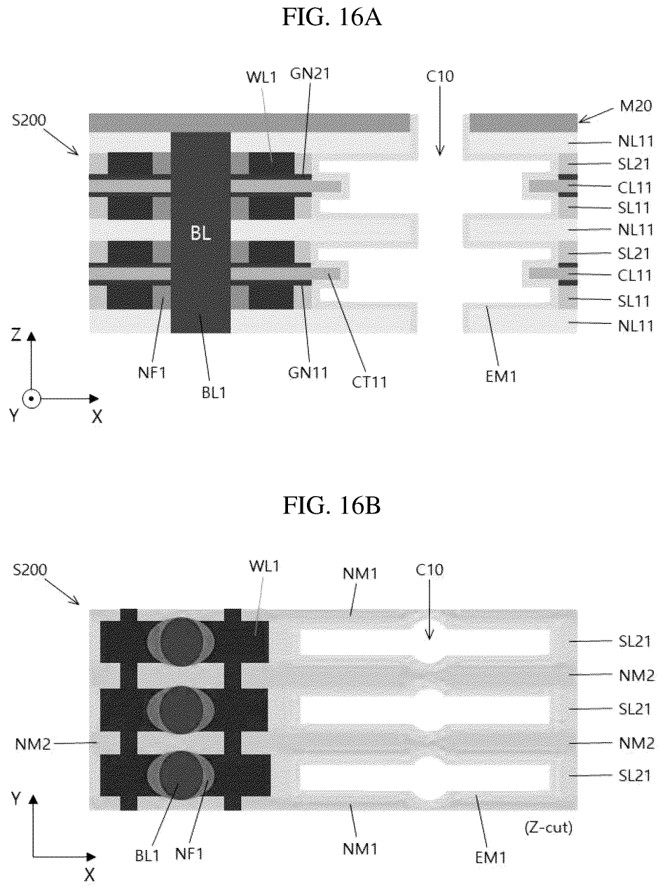

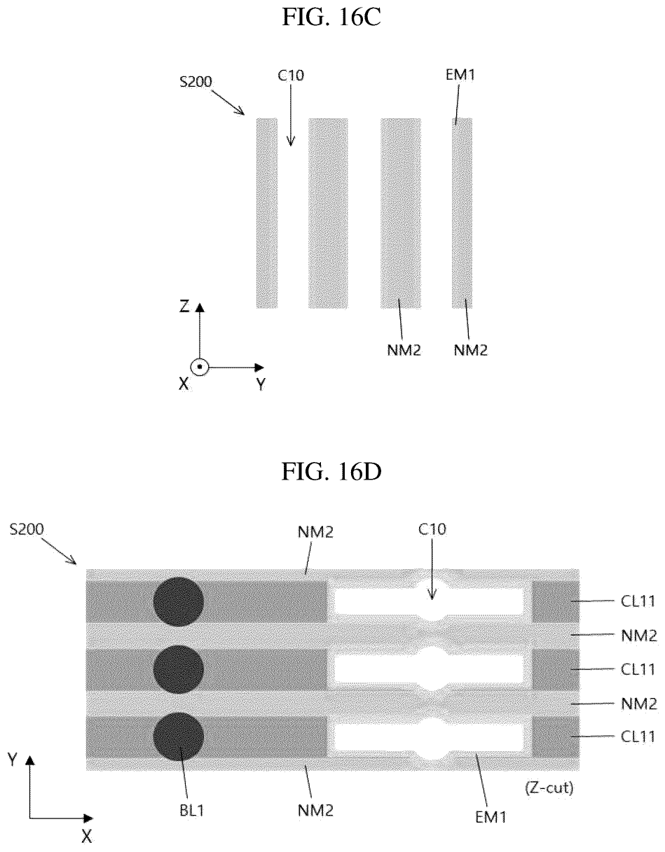

Referring to FIGS. 16A to 16D, an electrode member EM1 may be formed connected (contacted) with the protruding channel portion CT11 on the inner side of the second recess portion (R2 in FIG. 14A). The electrode member EM1 may be connected with the other end of the channel material layer CL11 of the transistor. The electrode member EM1 may be referred to as an electrode layer (first electrode layer) for a capacitor. The electrode member EM1 may be formed conformally along the surface shape of the first insulating layer NL11, the sacrificial layers SL11, SL12, the gate insulating layers GN11, GN21, and the protruding channel portion CT11. The electrode member EM1 may be formed, for example, by an ALD process.

The electrode member EM1 may be formed to contact the exposed top surface and side surfaces of the protruding channel portion CT11. Thus, the contact area between the electrode member EM1 and the protruding channel portion CT11, that is, between the electrode member EM1 and the channel material layer CL11, may be quite large, and the contact resistance between them may be low.

Referring to FIGS. 17A to 17D, a second etching part C20 may be formed in the area corresponding to the first etching part (C10 of FIG. 13A) in the capacitor forming area. The second etching portion C20 may be formed by etching a portion of the electrode member EM1. The second etching portion C20 may have a vertical hole structure. Through the process of this step, the electrode member EM1 may be separated into individual capacitor regions. In other words, the electrode member EM1 may be separated into unit cell regions.

According to one embodiment, the second etchback portion C20 may be formed by an etchback process on the portion of the electrode member EM1 formed on the inner wall of the first etchback portion (C10 in FIG. 16A). The second etch portion C20 may be a hole region substantially identical to the first etch portion (C10 in FIG. 16A).

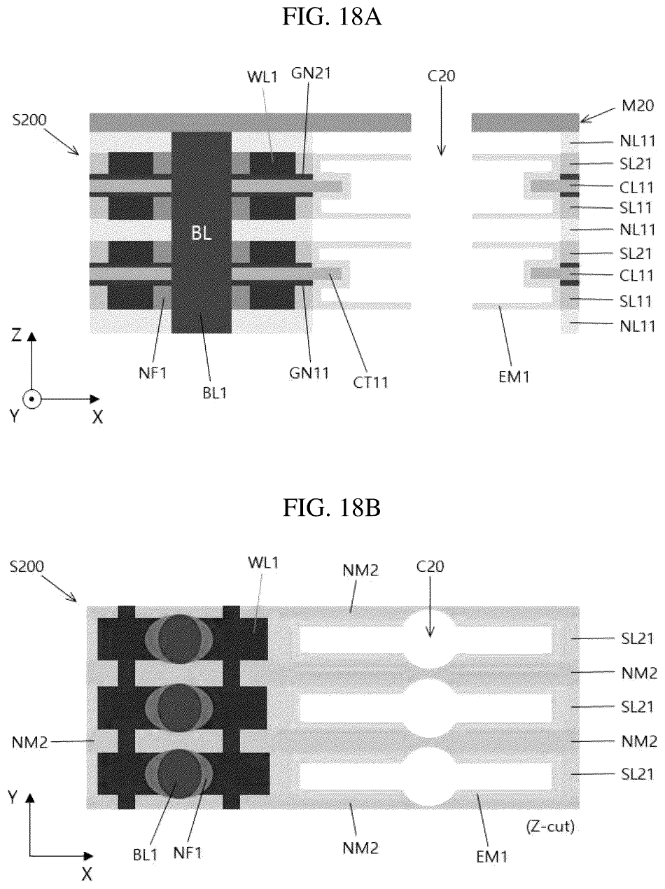

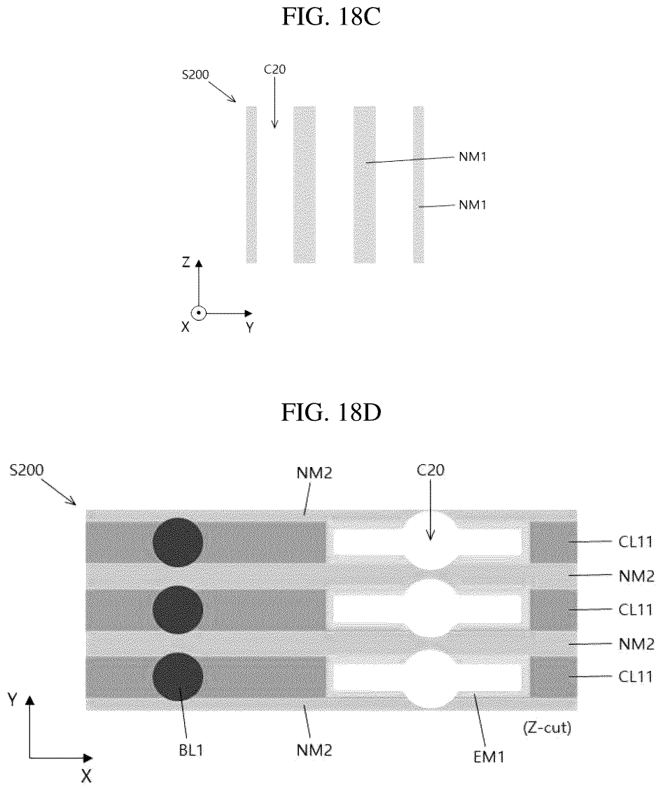

Referring to FIGS. 18A to 18D, after forming the electrode member EM1, the first insulating layer NL11 may be recessed (etched) in the capacitor forming region to expose an outer surface of the electrode member EM1. This may enable the formation of a fully cylindrical capacitor.

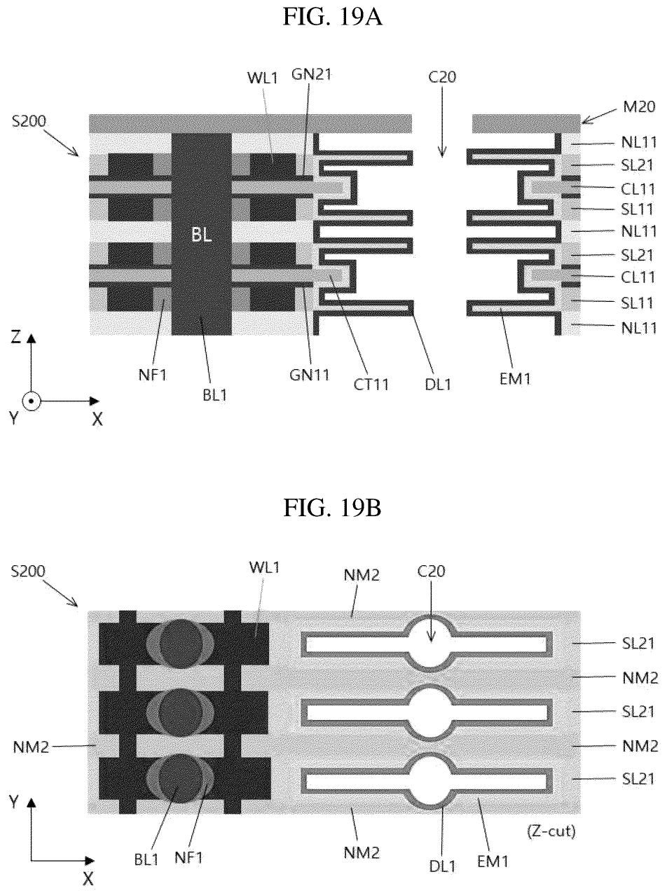

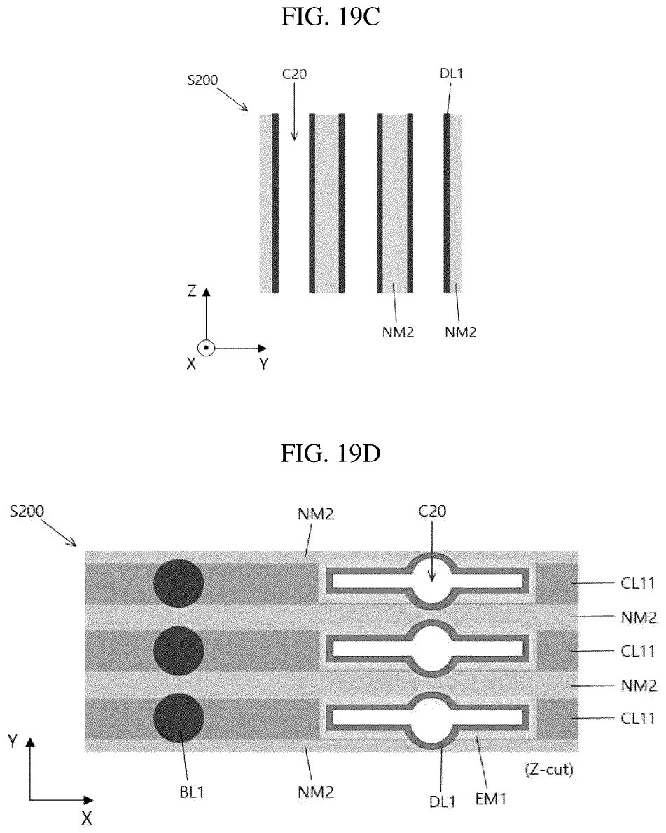

Referring to FIGS. 19A to 19D, a dielectric layer DL1 may be formed on the electrode member EM1 in the capacitor forming region. The dielectric layer DL1 may be a dielectric layer for a capacitor. The dielectric layer DL1 may be formed conformally along the surface shape of the electrode member EM1. The dielectric layer DL1 may be formed (deposited), for example, by an ALD process. The dielectric layer DL1 may be formed to include at least one of various dielectric materials. For example, the dielectric layer DL1 may comprise a high-k material having a higher dielectric constant than silicon nitride. The specific material of the dielectric layer DL1 may be varied.

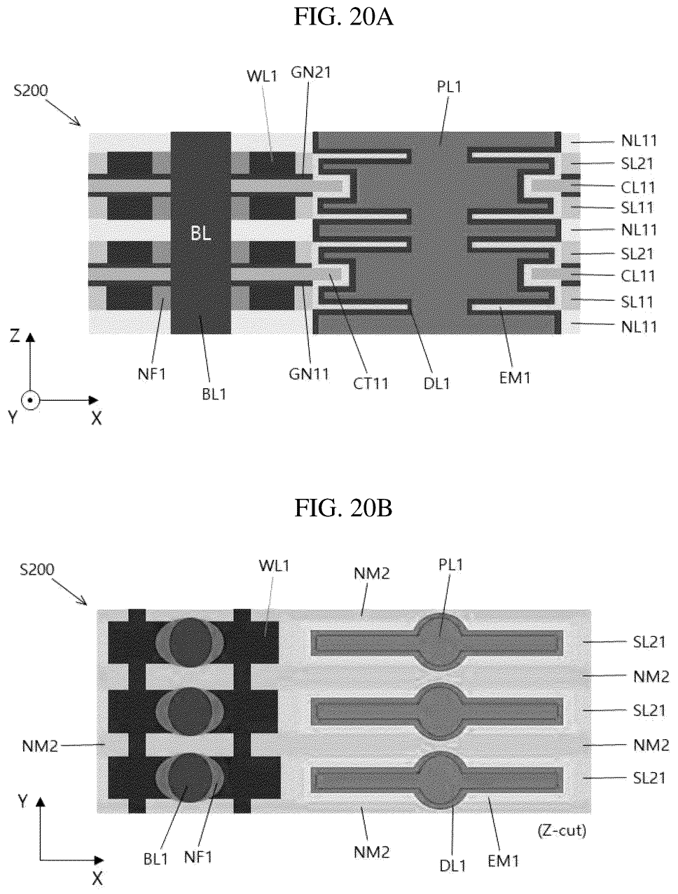

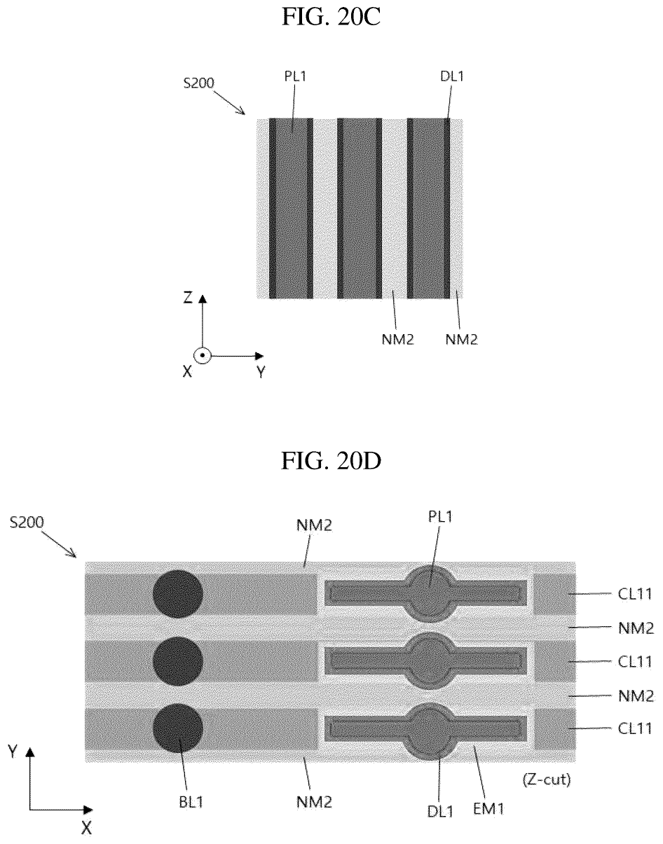

Referring to FIGS. 20A to 20D, a plate electrode PL1 may be formed on the dielectric layer DL1 in the capacitor forming region. The plate electrode PL1 may be referred to as an electrode layer (second electrode layer) for the capacitor. The plate electrode PL1 may be formed to fill the space between the second etching portion (C20 in FIG. 19A) and the interior of the electrode member EM1 and the electrode member EM1. The plate electrode PL1 may be formed to include one or more of a variety of electrode materials used in semiconductor device processes. A plurality of plate electrodes PL1 may be connected in a line. The electrode member EM1 and the dielectric layer DL1 and the plate electrodes PL1 may constitute a capacitor.

The second mask member (M20 in FIG. 19A) may then be removed. However, in some cases, the timing of the removal of the second mask member (M20 in FIG. 19A) may vary.

According to an embodiment of the present disclosure, a capacitor may be formed in contact with the exposed top surface and sides of the protruding channel portion CT11. The electrode member EM1 may have a structure extending upwardly, downwardly, and laterally with respect to the protruding channel portion CT11 while contacting the upper surface and sides of the protruding channel portion CT11. The dielectric layer DL1 may be disposed to contact the inner surface and the outer surface of the electrode member EM1. The plate electrode PL1 may be disposed to contact the dielectric layer DL1 while filling the inner space and the outer space of the electrode member EM1. According to this embodiment, by greatly enlarging the contact area between the channel layer and the capacitor and increasing the effective area of the capacitor dielectric layer, a stacked memory device may achieve low contact resistance and high characteristics.

While FIGS. 16A through 20D exemplarily show and describe a method of forming the above capacitor, in some cases, the method of forming the above capacitor and the specific structure of the above capacitor may be varied.

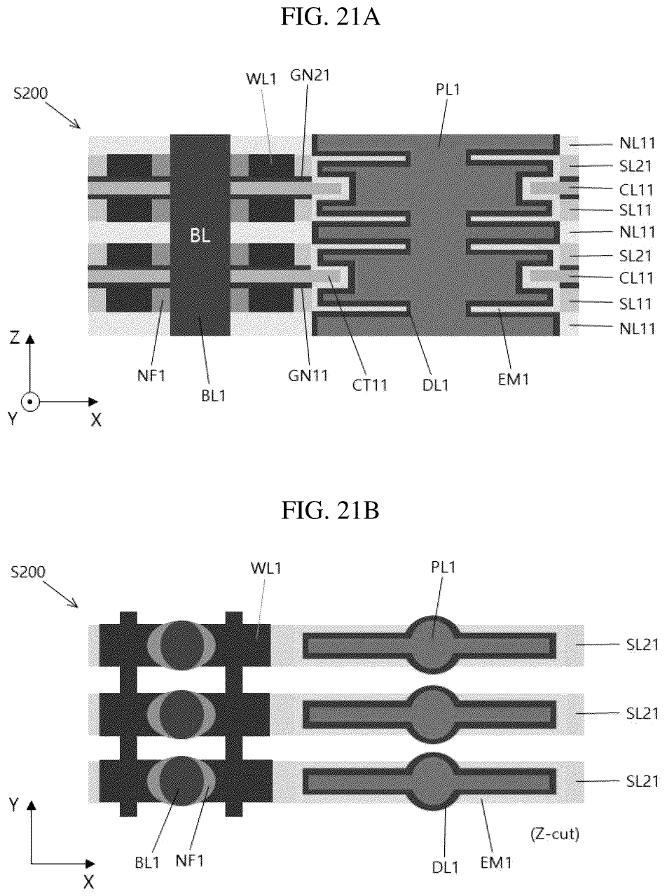

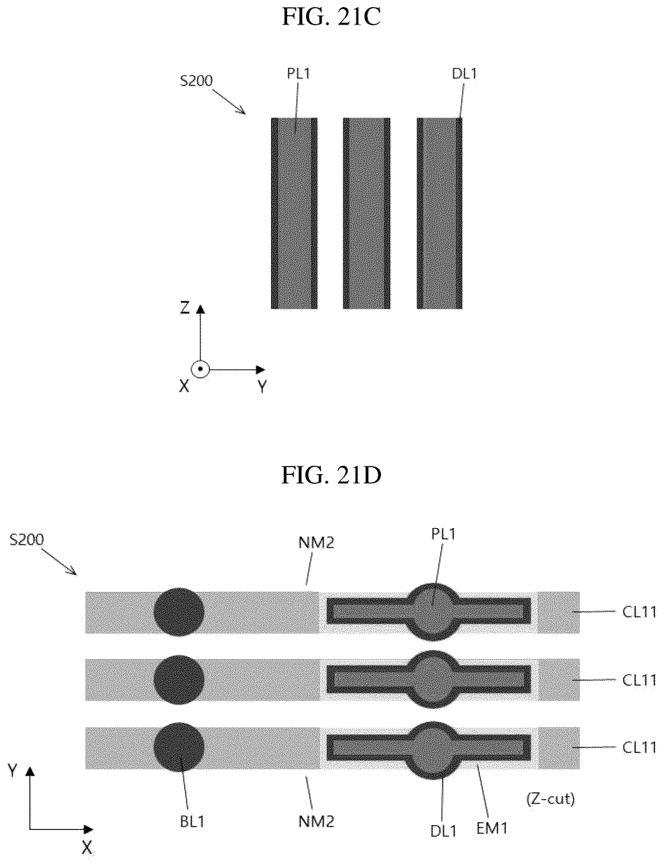

Referring to FIGS. 21A to 21D, the second separation material (M42 of FIGS. 20B to 20D) may be removed from the structure S200. For example, the second separation material (M42 in FIGS. 20B to 20D) may be selectively removed by utilizing a wet etching process having etching selectivity on the second separation material (NM42 in FIGS. 20B to 20D).

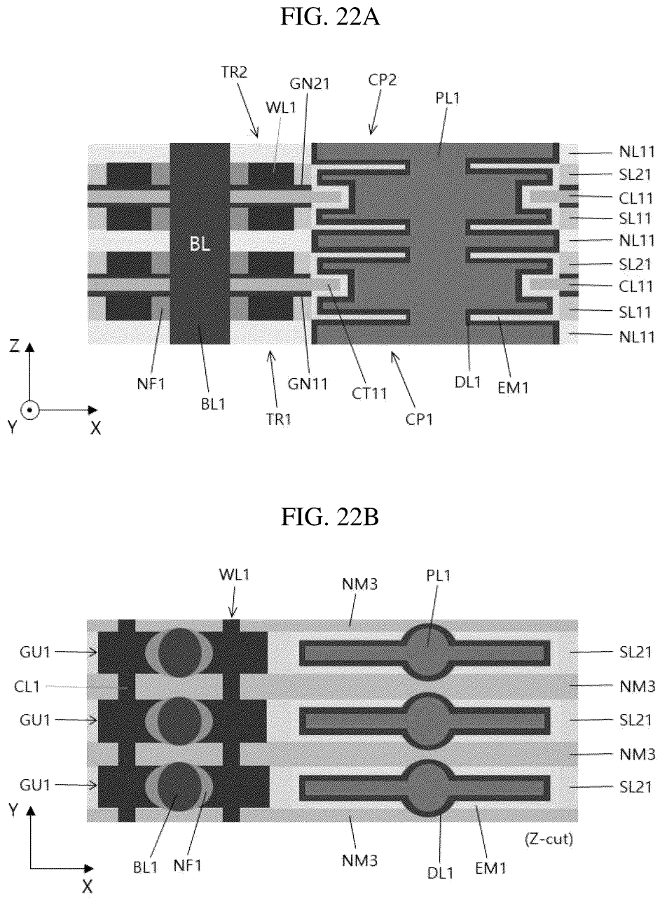

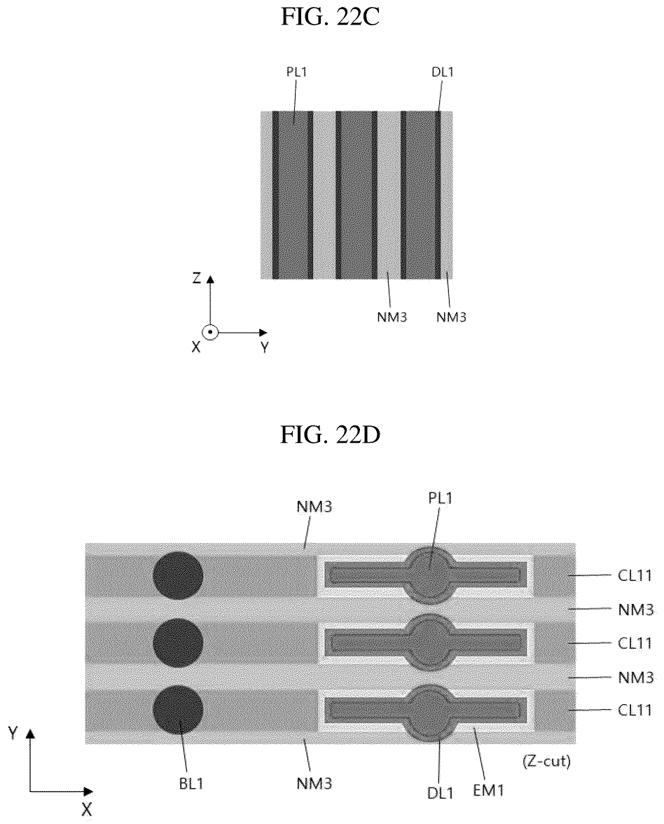

Referring to FIGS. 22A to 22D, a third separating material (M43) may be filled in the space from which the second separating material (NMC2 of FIGS. 20B to 20D) has been removed. The space around the plurality of patterned portions may be filled with the third separating material (M43). The third separation material (M43) may be filled in the surrounding spaces of the transistors and capacitors, etc. The third separation material NM3 may be formed (deposited), for example, by an ALD process, but is not limited thereto.

The third separation material (M43) may be referred to as a “separation material layer” or “separation material layer pattern” or “separation membrane”. The third separation material NM3 may be formed from or comprising, for example, but not limited to, an oxide, such as a silicon oxide. The material of the third separation material NM3 may be varied.

In some cases, the processes of FIGS. 21A through 21D and FIGS. 22A through 22D may be omitted.

In the device structure of FIG. 22A, the lower channel material layer CL11 and the corresponding word line WL1 and the gate insulating layers GN11, GN21 therebetween may constitute the first transistor TR1. In addition, the lower electrode member EM1 electrically connected to the first transistor TR1 on a side of the first transistor TR1, the dielectric layer DL1 in contact with the lower electrode member EM1, and the plate electrode PL1 may constitute the first capacitor CP1. Further, the first transistor TR1 and the first capacitor CP1 may constitute one memory cell (lower memory cell). The first transistor TR1 and the first capacitor CP1 may be arranged in a horizontal direction.

Furthermore, the upper channel material layer CL11 and the corresponding word line WL1 and the gate insulating layers GN11, GN21 therebetween may constitute the second transistor TR2. In addition, the upper electrode member EM1 electrically connected to the second transistor TR2 on the side of the second transistor TR2, the dielectric layer DL1 in contact with the upper electrode member EM1, and the plate electrode PL1 may constitute the second capacitor CP2. Further, the second transistor TR2 and the second capacitor CP2 may be the to constitute one memory cell (upper memory cell). The second transistor TR2 and the second capacitor CP2 may be arranged in a horizontal direction. The second transistor TR2 may be disposed on top of the first transistor TR1, and the second capacitor CP2 may be disposed on top of the first capacitor CP1.

Although not shown, an element structure such as FIGS. 22A to 22D may be repeatedly disposed in the Z-axis direction, may be repeatedly disposed in the X-axis direction, and may be repeatedly disposed in the Y-axis direction. According to these embodiments of the present disclosure, it is possible to realize a memory device that may have excellent performance and operation characteristics while being able to significantly improve integration. The memory device may be a dual gate type stacked memory having a horizontal arrangement and a stacked structure. Further, the memory device according to one embodiment of the present disclosure may be a vertical DRAM device or a three-dimensional DRAM device. Further, the memory device according to one embodiment of the present disclosure may be a horizontal stacked DRAM

Hereinafter, a memory device according to one embodiment of the present disclosure will be further described with reference to FIGS. 22A through 22D.

Referring now to FIGS. 22A through 22D, a memory device according to one embodiment of the present disclosure may include a plurality of memory cells stacked in a vertical direction. Each of the plurality of memory cells may include a transistor and a capacitor electrically connected therewith laterally to the transistor. The transistors may correspond to TR1 and TR2, and the capacitors may correspond to CP1 and CP2. The transistor may include a channel material layer CL11 and a word line WL1 disposed opposite thereto, and gate insulating layers GN11, GN21 disposed therebetween. The capacitor may include an electrode member (EM1) electrically connected with the transistor, a dielectric layer (DL1) disposed on a surface of the electrode member (EM1), and a plate electrode (PL1) disposed on a surface of the dielectric layer (DL1). Further, the memory device may include a bit line BL1 connected to a plurality of transistors of the plurality of memory cells. The bit lines BL1 may extend in a vertical direction.

The channel material layer CL11 may comprise an oxide semiconductor or a non-oxide semiconductor. The oxide semiconductor may include an amorphous oxide semiconductor (AOS). The oxide semiconductor may include at least one selected from the group consisting of, for example, indium gallium zinc oxide (IGZO), zinc tin oxide (ZTO), indium tin oxide (ITO), and the like. The channel material layer CL11 may be configured to include a polycrystalline semiconductor or an amorphous semiconductor. The channel material layer CL11 may also be configured to include silicon, germanium, or silicon-germanium. However, the specific material of the channel material layer CL11 is not limited to the above, and may be varied. The channel material layer CL11 may be monolayer or multilayer.

The word line WL1 may include a plurality of gate unit structures GU1 spaced apart from each other, and a connection line portion CL1 connecting the plurality of gate unit structures GU1. According to one embodiment, the plurality of gate unit structures GU1 may be disposed between the plurality of bit lines BL1 and the plurality of the capacitors, and the connecting line portion CL1 may have a narrower width than each of the plurality of gate unit structures GU1 and may be disposed to connect the plurality of gate unit structures GU1 in an extension direction of the word line WL1. The plurality of gate unit structures GU1 may be seen as being disposed between the plurality of bit lines BL1 and the plurality of electrode members EM1. Further, the plurality of gate unit structures GU1 may be disposed on each of the two sides of the bit line BL1, and the connection line portion CL1 may also be disposed on each of the two sides of the bit line BL1. Further, the transistor may have a dual gate structure. Two word lines WL1 disposed on the upper and lower sides of the one channel material layer CL11 may constitute a dual gate structure.

According to one embodiment, a sacrificial insulating layer, i.e., a sacrificial layer SL11, SL21, may be provided between each of the plurality of gate unit structures GU1 and the corresponding electrode member EM1. The gate unit structures GU1 may be contacted on a first side of the sacrificial layer SL11, SL21, and the electrode members EM1 may be contacted on a second side of the sacrificial layer SL11, SL21. Further, between the plurality of gate unit structures GU1 there may be a separation material membrane, i.e., a third separation material NM3, which is a separate layer of material from the sacrificial layers SL11, SL21. The third separation material NM3 may be composed of a material different from the sacrificial layers SL11, SL21.

According to one embodiment, the gate unit structure GU1 may have a concave shaped side facing the bit line BL1 when viewed from above (see FIG. 22B). A filling insulating layer NF1 may be disposed between the concave side of the gate unit structure GU1 and the side of the bit line BL1.

According to one embodiment, the channel material layer CL11 may include a protruding channel portion CT11 that protrudes into the capacitor formation region, and the electrode member EM1 may be disposed to contact the top surface and the sides of the protruding channel portion CT11. The electrode member EM1 may have a structure that extends upwardly, downwardly, and laterally with respect to the protruding channel portion CT11 while contacting the top surface and sides of the protruding channel portion CT11. The dielectric layer DL1 may be disposed to contact the inner surface and the outer surface of the electrode member EM1. The plate electrode PL1 may be disposed to contact the dielectric layer DL1 while filling the inner space and the outer space of the electrode member EM1. According to such an embodiment, by greatly expanding the contact area between the channel layer and the capacitor and increasing the effective area of the capacitor dielectric layer, low contact resistance and high characteristics may be obtained.

According to one embodiment, the electrode member EM1 may be configured to form a U-shaped bend at each of the bottom and top of the protruding channel portion CT11. Similarly, the dielectric layer DL1 may be configured to form U-shaped bend at each of the lower and upper sides of the protruding channel portion CT11. In this case, it may be more advantageous to increase the effective area of the capacitor. However, the specific structure of the capacitor is not limited to the foregoing, and may be varied in some cases.

In addition, a memory device according to one embodiment of the present disclosure may have structural and effects associated therewith, such as those illustrated in FIGS. 22A through 22D.

According to the embodiments of the present disclosure described above, it is possible to realize a memory device (stacked memory device) and a manufacturing method thereof that may increase integration and secure excellent performance, while at the same time being easy to manufacture. Furthermore, according to embodiments of the present disclosure, a memory device (memory device) and a manufacturing method thereof that may low contact resistance and high characteristics may be by greatly enlarging the contact area between a channel layer and a capacitor and increasing the effective area of a capacitor dielectric layer. Furthermore, according to one embodiment of the present disclosure, by forming a word line comprising a plurality of gate unit structures and a connecting line portion connecting them using a laminate patterned in a predetermined shape, a dual gate structure may be formed, thereby securing ease of process and improving operating characteristics.

In one example, a memory device according to embodiments of the present disclosure may comprise a horizontally stacked DRAM device. However, at least some of the device structures and manufacturing methods according to embodiments of the present disclosure may be applicable not only to DRAM devices, but also to other memory devices (e.g., PRAM, RRAM, SRAM, flash memory, MRAM, FRAM, etc.) or technologies implementing logic devices with integrated logic circuits.

While the present disclosure has been described with reference to the embodiments illustrated in the figures, the embodiments are merely examples, and it will be understood by those skilled in the art that various changes in form and other embodiments equivalent thereto can be performed. Therefore, the technical scope of the disclosure is defined by the technical idea of the appended claims.

The drawings and the forgoing description gave examples of the present invention. The scope of the present invention, however, is by no means limited by these specific examples. Numerous variations, whether explicitly given in the specification or not, such as differences in structure, dimension, and use of material, are possible. The scope of the invention is at least as broad as given by the following claims.

What is claimed is:

1. A method of manufacturing a memory device, comprising:
forming a laminate including a first insulating layer and a first sacrificial layer sequentially laminated on the first insulating layer, a 1-1 gate insulating layer, a channel material layer, a 1-2 gate insulating layer, and a second sacrificial layer;
patterning the laminate to form a patterned laminate having at least one pattern portion, wherein the pattern portion has a shape extending in a first direction and an etched region is provided on both sides of the pattern portion along a second direction perpendicular to the first direction;
filling a separation material into the etched region on both sides of the at least one pattern portion to define a structure including at least the patterned laminate;
forming a first vertical hole penetrating the pattern portion in a transistor formation region of the structure and recessing the first and second sacrificial layers around the first vertical hole to form a first recess portion;
forming a word line in the first recess portion to define a transistor including the word line;
forming a bit line connected to the channel material layer in an area corresponding to the first vertical hole of the structure;
forming a second recessed portion exposing the 1-1 and 1-2 gate insulating layers by recessing the first and second sacrificial layers in a capacitor formation area adjacent to the transistor formation area of the structure;
defining a protruding channel portion from the channel material layer by recessing the channel material layer and the 1-1 and 1-2 gate insulating layers in the second recessed portion so that the protruding channel portion protruding into the second recessed portion remains and upper, lower, and side surfaces of the protruding channel portion are exposed; and
forming a capacitor in contact with the exposed upper, lower, and side surfaces of the protruding channel portion in the capacitor formation area.

2. The method of claim 1, wherein the first insulating layer comprises silicon oxide, and the first and second sacrificial layers comprise silicon nitride.

3. The method of claim 1, wherein the separation material has a different material composition from the first insulating layer and the first and second sacrificial layers.

4. The method of claim 1, wherein the patterned laminate is formed to include a plurality of pattern portions spaced apart from each other in the second direction and a pattern connection portion connecting the plurality of pattern portions in the second direction.

5. The method of claim 1,
wherein the word line includes a gate unit structure formed corresponding to the channel material layer of the transistor formation region,
wherein a plurality of the gate unit structures is arranged spaced apart from each other in the second direction, and the word line further includes a connection line portion connecting the plurality of gate unit structures in the second direction,
wherein the connection line portion is formed at a position corresponding to the pattern connection portion.

6. The method of claim 4, before forming the bit line, further comprising:
removing the separation material from the structure;
removing the channel material layer portion arranged in the pattern connection portion from the patterned laminate; and
filling a space around the plurality of pattern portions with a second separation material.

7. The method of claim 1, the step of forming the word line to define the transistor comprises:
forming a word line material layer filling at least a portion of the first vertical hole and the first recess portion in the transistor formation region;
forming a through hole by etching a region corresponding to the first vertical hole in the word line material layer;
forming a recess region by recessing a portion of the word line material layer exposed through the through hole so that one end of the channel material layer protrudes toward the through hole more than the word line material layer; and
forming a filling insulating layer in the recess region.

8. The method of claim 1,
wherein the patterned laminate is formed to include a plurality of the pattern portions spaced apart from each other in the second direction and a pattern connection portion connecting the plurality of the pattern portions in the second direction,
wherein the step of forming the word line to define the transistor comprises:
forming a word line material layer filling at least a portion of the first vertical hole and the first recess portion in the transistor formation region;
removing the separation material from the structure;
removing a portion of the channel material layer arranged in the pattern connection portion from the patterned laminate;
filling a space around the plurality of pattern portions with a second separation material;
forming a through hole by etching a region corresponding to the first vertical hole in the word line material layer;
forming a recess region by recessing a portion of the word line material layer exposed through the through hole so that one end of the channel material layer protrudes toward the through hole more than the word line material layer; and
forming a filling insulating layer within the recessed region.

9. The method of claim 1, after forming an etched portion by etching the pattern portion in the capacitor formation region of the structure further comprising:
forming the second recess portion injecting a wet etching solution through the etched portion.

10. The method of claim 1, wherein the step of defining the protruding channel portion comprises:
recessing the channel material layer in the second recessed portion; and
removing the 1-1 and 1-2 gate insulating layers from the second recessed portion.

11. The method of claim 1, wherein the step of forming the capacitor includes:
forming an electrode member in contact with the upper, lower, and side surfaces of the first protruding channel member on the inner surface of the second recessed portion;
forming a dielectric layer on the electrode member; and
forming a plate electrode on the dielectric layer.

12. The method of claim 1, after forming the electrode member, further comprising:
recessing the first insulating layer in the capacitor formation region to expose the outer surface of the electrode member is further included; and
sequentially forming the dielectric layer and the plate electrode after exposing the outer surface of the electrode member.

13. The method of claim 1,
wherein the first insulating layer, the first sacrificial layer, the 1-1 gate insulating layer, the channel material layer, the 1-2 gate insulating layer, and the second sacrificial layer form one unit laminate,
wherein the unit laminate is repeatedly laminated on a substrate in the step of forming the laminate.

14. The method of claim 13,
wherein the transistor is a first transistor, and the capacitor is a first capacitor,
wherein the memory device further includes a second transistor disposed on the first transistor and a second capacitor disposed on the first capacitor.

15. A memory device comprising a plurality of memory cells stacked in a vertical direction, comprising:
each of the plurality of memory cells includes a transistor and a capacitor electrically connected to the side of the transistor,
wherein the transistor includes a channel material layer, a word line disposed opposite the transistor, and a gate insulating layer disposed between them,
wherein the capacitor includes an electrode member electrically connected to the transistor, a dielectric layer disposed on a surface of the electrode member, and a plate electrode disposed on a surface of the dielectric layer,
wherein a bit line extending in a vertical direction is provided, which is connected to a plurality of transistors of the plurality of memory cells,
wherein the channel material layer includes a protruding channel portion protruding into a capacitor formation region, the electrode member is disposed to contact upper, lower, and side surfaces of the protruding channel portion,
wherein the word line includes a plurality of gate unit structures spaced apart from each other and a connection line portion connecting the plurality of gate unit structures.

16. The device of claim 15,
wherein the electrode member has a structure that extends upwardly and laterally with respect to the protruding channel portion while contacting the upper surface and side surfaces of the protruding channel portion,
wherein the dielectric layer is arranged to contact the inner surface and the outer surface of the electrode member,
wherein the plate electrode is arranged to contact the dielectric layer while filling the inner space and the outer space of the electrode member.

17. The device of claim 15,
wherein the plurality of gate unit structures is arranged between the plurality of bit lines and the plurality of capacitors,
wherein the connection line portion is arranged to have a narrower width than each of the plurality of gate unit structures and to connect the plurality of gate unit structures in the extension direction of the word line.

18. The device of claim 15,
wherein the plurality of gate unit structures are arranged on each of the two sides of the bit line,
wherein the memory device in which the connection line portion is arranged on each of the two sides of the bit line.

19. The device of claim 15, wherein the gate unit structure has a concave side surface when viewed from above toward the bit line.

20. The device of claim 15,
wherein a sacrificial insulating layer is disposed between each of the plurality of gate unit structures and the electrode member corresponding thereto,
wherein a separation material film composed of a different material from the sacrificial insulating layer is disposed between the plurality of gate unit structures.
